(19) United States
(12) Patent Application Publication
(10) Pub. No.: US 2026/0012145 A1
(43) Pub. Date: Jan. 8, 2026

(54) POWER AMPLIFIER AND MANUFACTURING METHOD THEREOF

(71) Applicants: SAMSUNG ELECTRONICS CO., LTD., Suwon-si (KR); FOUNDATION OF SOONGSIL UNIVERSITY-INDUSTRY COOPERATION, Seoul (KR)

(72) Inventors: Youngtek OH, Suwon-si (KR); Changkun PARK, Seoul (KR); Geonwook YOO, Seoul (KR); Kyungwook HWANG, Suwon-si (KR); Junsik HWANG, Suwon-si (KR)

(73) Assignees: SAMSUNG ELECTRONICS CO., LTD., Suwon-si (KR); FOUNDATION OF SOONGSIL UNIVERSITY-INDUSTRY COOPERATION, Seoul (KR)

(21) Appl. No.: 19/008,155

(22) Filed: Jan. 2, 2025

(30) Foreign Application Priority Data
Jul. 3, 2024 (KR) 10-2024-0087816

(51) Int. Cl. H03F 3/21; H03F 3/45; H10D 30/47; H10D 62/85

(52) U.S. Cl. CPC H03F 3/21; H03F 3/45179; H10D 30/475; H10D 62/8503

(57) ABSTRACT

A power amplifier includes a first transistor connected between a first output node and a common node and including a gate connected to a first input node, a second transistor connected between a second output node and the common node and including a gate connected to a second input node, and a third transistor connected between the common node and ground and including a gate connected to a first switch node. The first transistor and the second transistor each includes a depletion mode (d-mode) high electron mobility transistor (HEMT) including a group III-V semiconductor material and operating normally-on, and the third transistor includes a metal oxide semiconductor field effect transistor (MOSFET) including a group IV semiconductor material.

### CROSS-REFERENCE TO RELATED APPLICATION

This application is based on and claims priority under 35 U.S.C. § 119 to Korean Patent Application No. 10-2024-0087816, filed on Jul. 3, 2024, in the Korean Intellectual Property Office, the disclosure of which is incorporated by reference herein in its entirety.

### BACKGROUND

### 1. Field

The disclosure relates to a power amplifier and a method of manufacturing the power amplifier. In particular, the disclosure relates to a nitride power amplifier including a normally-on high electron mobility transistor (HEMT) and a method of manufacturing the power amplifier.

### 2. Description of Related Art

Interest in reduction of power consumption due to green energy policies is increasing. To this end, an increase in power conversion efficiency is an essential factor. In power conversion, the efficiency of power switching devices determines the overall power conversion efficiency.

Currently, most commonly used power devices are metal oxide semiconductor field effect transistors (MOSFETs) or insulated-gate bipolar transistors (IGBTs) using silicon, but there is a limit to the increase in the efficiency of such devices due to the material limitations of silicon. To solve this problem, research is being conducted to increase conversion efficiency by manufacturing transistors using nitride semiconductors such as gallium nitride (GaN).

However, when a gate voltage is 0 V (in a normal state), a high electron mobility transistor (HEMT) structure using GaN is in an ‘on’ state in which current flows due to low resistance between a drain electrode and a source electrode. Accordingly, current and power consumption occur, and there is a disadvantage in that a negative voltage (e.g., −5 V) needs to be applied to the gate electrode to place the HEMT structure in an off state.

In order to solve this problem, related art methods implement normally-off operations using various structures, but general normally-off structures have problems in which characteristics deteriorate such as low current density and internal pressure, compared to normally-on structures. Therefore, research is being conducted to implement normally-off by cascading normally-on GaN HEMTs with normally-off FETs.

FIGS. 1A and 1B illustrate nitride power amplifiers 1 and 2 of the related art. Referring to FIG. 1A, the nitride power amplifier 1 includes a normally-on gallium nitride (GaN) high electron mobility transistor (HEMT) H1 and a silicon metal oxide semiconductor field effect transistor (MOSFET) M1. The nitride power amplifier 1 is a semiconductor structure that operates normally-off by bonding and packaging of the normally-on GaN HEMT H1 and the silicon MOSFET M1 into one package. In other words, the nitride power amplifier 1 uses normally-off characteristics of the silicon MOSFET M1 to minimize power consumption due to a normally-on operation, which was a disadvantage of the high-power GaN HEMT H1, and cascades the normally-on GaN HEMT H1 to perform a normally-off operation.

However, because a drain electrode DE of the silicon MOSFET M1 shown in FIG. 1A is connected to a source electrode SE of the GaN HEMT H1 and involves amplification of an alternating current (AC) signal, both the GaN HEMT H1 and the silicon MOSFET M1 affect a result of the amplification of the AC signal of the entire nitride power amplifier 1. In other words, the silicon MOSFET M1, which is used to solve a problem of a negative threshold voltage of the GaN HEMT H1, may be problematic, as it affect the characteristics of the AC signal of the nitride power amplifier 1.

Referring to FIG. 1B, the nitride power amplifier 2 includes a pair of GaN HEMTs H2 and H3 and a pair of silicon MOSFETs M2 and M3. The nitride power amplifier 2 shown in FIG. 1B is configured as a differential amplifier and has a relative advantage in terms of noise and gain compared to the nitride power amplifier 1 shown in FIG. 1A. However, similar to the nitride power amplifier 1 shown in FIG. 1A, the nitride power amplifier 2 may still have a noise problem due to the silicon MOSFET M1.

### SUMMARY

One or more embodiments of the disclosure may reduce miniaturization and power gain deterioration of a nitride power amplifier through heterogeneous integration processes of a gallium nitride (GaN) high electron mobility transistor (HEMT) and a silicon metal oxide semiconductor field effect transistor (MOSFET).

However, the disclosure is not limited thereto, and as such, the technical problems addressed by the embodiments the disclosure is not limited to the technical problems as described above, and other technical problems may be inferred from the following embodiments.

Additional aspects will be set forth in part in the description which follows and, in part, will be apparent from the description, or may be learned by practice of the presented embodiments of the disclosure.

According to an aspect of the disclosure, there is provided a power amplifier including: a first transistor connected between a first output node and a common node, the first transistor including a gate connected to a first input node; a second transistor connected between a second output node and the common node, the second transistor including a gate connected to a second input node; and a third transistor connected between the common node and ground, the third transistor including a gate connected to a first switch node, wherein each of the first transistor and the second transistor includes a depletion mode (d-mode) high electron mobility transistor (HEMT) including a group III-V semiconductor material, wherein each of the first transistor and the second transistor is configured to operate normally-on, and wherein the third transistor includes a metal oxide semiconductor field effect transistor (MOSFET) including a group IV semiconductor material.

According to another aspect of the disclosure, there is provided a method of manufacturing a power amplifier, the method including: forming a metal oxide semiconductor field effect transistor (MOSFET) on a substrate including a group IV semiconductor material; forming a plurality of grooves in an upper surface of the substrate; transferring a first and second depletion mode (d-mode) high electron mobility transistors (HEMTs) into respective one of the plurality of grooves, each of the first and the second d-mode HEMTs including a group III-V semiconductor material and operate normally-on; connecting a drain of the first d-mode HEMT to a first output node, connecting a source of the first d-mode HEMT to a common node, and connecting a gate of the first d-mode HEMT to a first input node; connecting a drain of the second d-mode HEMT to a second output node, connecting a source of the second d-mode HEMT to the common node, and connecting a gate of the second d-mode HEMT to a second input node; and connecting a drain of the MOSFET to the common node, a source of the MOSFET to ground, and a gate of the MOSFET to a first switch node.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 1B illustrate nitride power amplifiers according to related art;

FIG. 2 is a plan view illustrating an electrode arrangement of a semiconductor device, according to an embodiment;

FIG. 3A is a cross-sectional view illustrating a schematic structure of the semiconductor device taken along line A-A′ of FIG. 2;

FIG. 3B is a cross-sectional view illustrating a schematic structure of the semiconductor device taken along line B-B′ of FIG. 2;

FIG. 3C is a cross-sectional view illustrating a schematic structure of the semiconductor device taken along line C-C′ of FIG. 2;

FIG. 4 is a plan view schematically illustrating an electrode arrangement structure of the semiconductor device shown in FIG. 2;

FIGS. 5A to 5F illustrate a process of manufacturing a power amplifier by integrating the semiconductor device shown in FIG. 2 on heterogeneous semiconductor substrates;

FIG. 6 is a plan view illustrating arrangement of a plurality of electrode pads included in a resulting power amplifier;

FIGS. 7A to 7C illustrate a process of wet transferring the semiconductor device shown in FIG. 2 onto heterogeneous semiconductor substrates;

FIGS. 8A to 8C illustrate various wiring forms for electrical connection with the semiconductor device shown in FIG. 2 in an electronic device, according to an embodiment;

FIG. 9 is a circuit diagram illustrating a power amplifier according to an embodiment;

FIG. 10 is a diagram for analyzing an equivalent circuit of a power amplifier through analysis of a small signal;

FIG. 11 is a circuit diagram illustrating a power amplifier according to another embodiment;

FIG. 12 is a circuit diagram illustrating a power amplifier according to another embodiment; and

FIG. 13 is a flowchart illustrating a method of manufacturing a power amplifier, according to an embodiment.

### DETAILED DESCRIPTION

Reference will now be made in detail to embodiments, examples of which are shown in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

General terms which are currently used widely have been selected for use in consideration of theirs functions in embodiments; however, such terms may be changed according to an intention of a person skilled in the art, precedents, advent of new technologies, etc. Further, in certain cases, terms have been arbitrarily selected, and in such cases, meanings of the terms will be described in detail in corresponding descriptions. Accordingly, the terms used in the embodiments should be defined based on their meanings and overall descriptions of the embodiments, not simply by their names.

In some descriptions of the embodiments, when a portion is described as being connected to another portion, the portion may be connected directly to another portion, or electrically connected to another portion with an intervening portion therebetween. When a portion “includes” an element, another element may be further included, rather than excluding the existence of the other element, unless otherwise described.

The terms “comprise” or “include” used in the embodiments should not be construed as including all components or operations described in the specification, and may be understood as not including some of the components or operations, or further including additional components or operations.

The descriptions of the following embodiments should not be construed as limiting the scope of rights, and matters that those skilled in the art may easily derive should be construed as being included in the scope of rights of the embodiments. Hereinafter, embodiments will be described in detail as an example, with reference to the attached drawings.

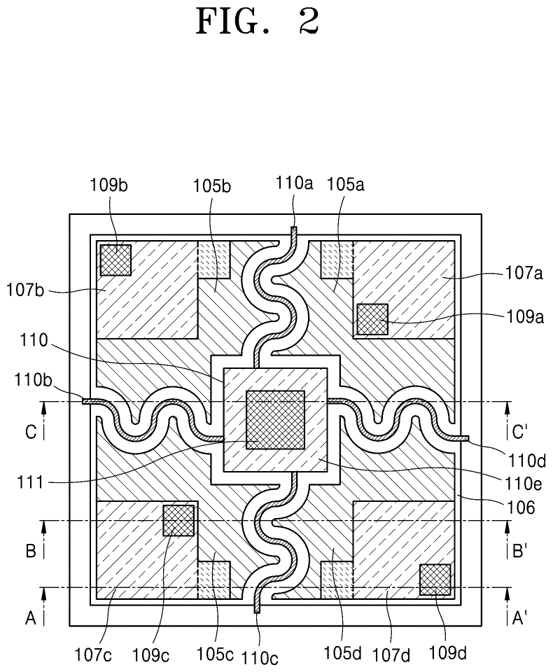

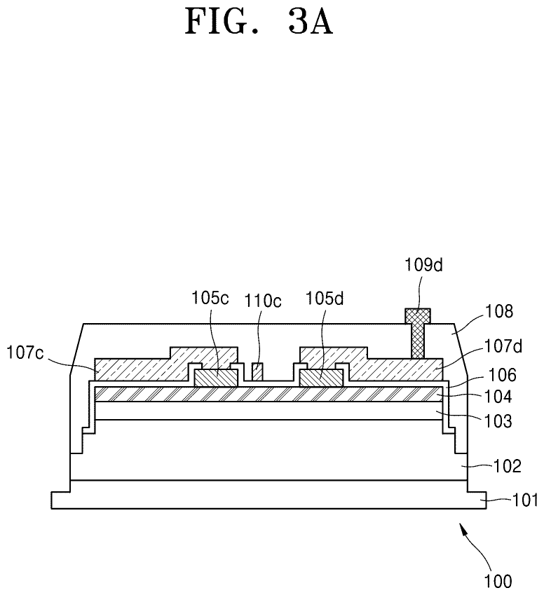

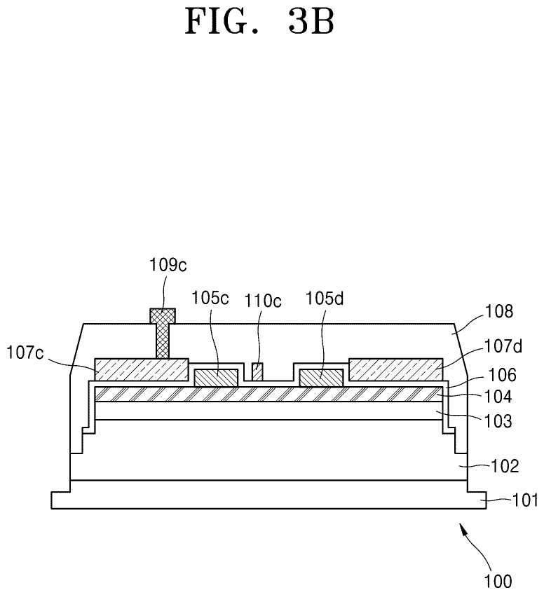

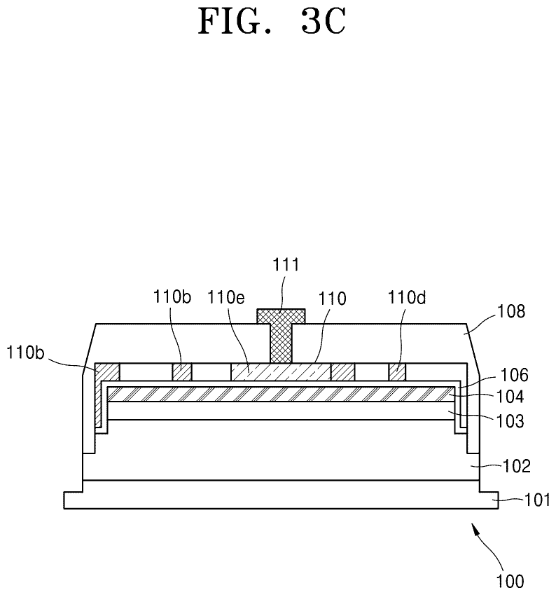

FIG. 2 is a plan view illustrating an electrode arrangement of a semiconductor device 100 according to an embodiment. FIG. 3A is a cross-sectional view illustrating a schematic structure of the semiconductor device 100 taken along line A-A′ of FIG. 2. FIG. 3B is a cross-sectional view illustrating a schematic structure of the semiconductor device 100 taken along line B-B′ of FIG. 2. FIG. 3C is a cross-sectional view illustrating a schematic structure of the semiconductor device 100 taken along line C-C′ of FIG. 2.

In FIG. 2, it is assumed that a gate insulating layer 106 and a passivation layer 108 described below are transparent for convenience in order to show arrangement relationships between first to fourth source/drains 105a, 105b, 105c, and 105d, first to fourth conductor layers 107a, 107b, 107c, and 107d, first to fourth source/drain electrodes 109a, 109b, 109c, and 109d, a gate 110, and a gate electrode 111, but the gate insulating layer 106 and the passivation layer 108 may not be actually transparent.

Referring to FIGS. 2, 3A, 3B, and 3C, the semiconductor device 100 according to an embodiment may include a substrate 101, a buffer layer 102 provided on the substrate 101, a channel layer 103 provided on the buffer layer 102, a barrier layer 104, provided on the channel layer 103, a plurality of sources/drains (e.g., a first sources/drains 105a, a second sources/drains 105b, a third sources/drains 105c, and a fourth 105d) on the barrier layer 104, a gate insulating layer 106 provided on the channel layer 103 and the barrier layer 104, a gate 110 provided on the gate insulating layer 106, a plurality of conductor layers (e.g., a first conductor layer 107a, a second conductor layer 107b, a third conductor layer 107c, and a fourth conductor layer 107d) provided on the gate insulating layer 106, a passivation layer 108 provided on the gate insulating layer 106, the gate 110, and the first to fourth conductor layers 107a, 107b, 107c, and 107d, a plurality of source/drain electrodes ((e.g., a first source/drain electrode 109a, a second source/drain electrode 109b, a third source/drain electrode 109c, and a fourth source/drain electrode 109d) electrically connected to the first to fourth conductor layers 107a, 107b, 107c, and 107d, respectively, a gate electrode 111 electrically connected to the gate 110. According to an embodiment, the gate insulating layer 106 may cover the channel layer 103 and the barrier layer 104. In some cases, the gate insulating layer 106 may be further provided on the buffer layer 102. According to an embodiment, the first conductor layer to fourth conductor layers 107a, 107b, 107c, and 107d may be electrically connected to the first to fourth sources/drains 105a, 105b, 105c, and 105d, respectively. According to an embodiment, the passivation layer 108 may cover the gate insulating layer 106, the gate 110, and the first to fourth conductor layers 107a, 107b, 107c, and 107d. For example, the passivation layer 108 may be configured to protect the semiconductor device 100. IN some cases, the passivation layer 108 may be further provided on the buffer layer 102. The first to the fourth source/drain electrode 109a, 109b, 109c, and 109d and the gate electrode 111 may penetrate the passivation layer 108.

The semiconductor device 100 may be a group III-V semiconductor device including a group III-V semiconductor material. For example, the semiconductor device 100 may be a high electron mobility transistor (HEMT).

The substrate 101 may be a growth substrate for manufacturing the semiconductor device 100. The substrate 101 shown in FIG. 3A may be removed before wet transfer of the semiconductor device 100 to be described below. For example, the substrate 101 may include a material that may be easily separated from the buffer layer 102 by a chemical lift-off method or a laser lift-off method. For example, the substrate 101 may include at least one of sapphire and silicon (Si), but the disclosure is not limited thereto. As such, the substrate 101 may include another material. The substrate 101 may include a variety of other materials capable of chemical lift-off or laser lift-off. When the substrate 101 is separated by the chemical lift-off method or the laser lift-off method, a lower surface of the semiconductor device 100, that is, a lower surface of the buffer layer 102, may have a very smooth and flat state.

According to an embodiment the buffer layer 102 is provided to prevent crystallinity of the channel layer 103 from deteriorating by mitigating differences in a lattice constant and a thermal expansion coefficient between the substrate 101 and the channel layer 103. The buffer layer 102 may have a single-layer structure or a multi-layer structure including a group III-V material, for example, at least one material selected from nitrides including at least one of Al, Ga, or In. The buffer layer 102 may be AlxlnyGa1-x-yN (0≤x≤1, 0≤y≤1, x+y≤1). The buffer layer 102 may have a single-layer structure or a multi-layer structure including at least one of AlN, GaN, AlGaN, InGaN, AlInN, AlGaInN, etc. According to an embodiment, a seed layer for growth of the buffer layer 102 may be provided between the substrate 101 and the buffer layer 102. However, the disclosure is not limited thereto, and as such, according to another embodiment, a seed layer may not be provided.

The channel layer 103 may include a material capable of generating a 2 dimensional electronic gas (2DEG) in the channel layer 103. The channel layer 103 is a layer forming a channel between a source and a drain. The channel layer 103 may have a single-layer structure or a multi-layer structure including a group III-V material, for example, at least one material selected from nitrides including at least one of Al, Ga, or In. The channel layer 103 may be AlxInyGa1-x-yN (0≤x≤1, 0≤y≤1, x+y≤1). For example, the channel layer 103 may include, but is not limited to, at least one of GaN, AlN, InN, and InGaN or AlGaN, AlInN, and AlInGaN. The channel layer 103 may be an undoped layer or a layer doped with impurities. A thickness of the channel layer 103 may be hundreds of nm or less.

The barrier layer 104 may include a group III-V semiconductor material different from the semiconductor material of the channel layer 103. For example, the barrier layer 104 may be different from the channel layer 103 in at least one of a polarization characteristic, an energy bandgap, or a lattice constant. However, the disclosure is not limited thereto, and as such, the barrier layer 104 may be different from the channel layer 103 in another manner. The barrier layer 104 may include a material having an energy bandgap greater than that of the channel layer 103. For example, the barrier layer 104 may have a multi-layer structure including a group III-V semiconductor material, for example, at least one material selected from nitrides including at least one of Al, Ga, or In. The barrier layer 104 may be, for example, AlxInyGa1-x-yN (0≤x≤1, 0≤y≤1, x+y≤1), and may include at least one material of GaN, InN, AlGaN, AlInN, InGaN, AlN, or AlInGaN. The energy bandgap of the barrier layer 104 may be adjusted by a composition ratio of Al and/or In.

The barrier layer 104 may be doped with an impurity. The impurity may be a p-type dopant capable of providing holes. For example, magnesium (Mg) may be used as the p-type dopant. However, the disclosure is not limited thereto, and as such, according to another embodiment, another material may be used as the p-type dopant. A doping concentration of the barrier layer 104 may be set to obtain a desired threshold voltage and on-resistance.

The barrier layer 104 may have a relatively higher energy bandgap than the channel layer 103 and may have a higher electrical polarization rate than the channel layer 103. Therefore, the 2DEG may be induced in the channel layer 103 having a relatively low electrical polarization rate by the barrier layer 104. For example, the barrier layer 104 may be referred to as a channel supply layer or a 2DEG supply layer. The 2DEG may be formed in a region of the channel layer 103 below an interface between the channel layer 103 and the barrier layer 104. The 2DEG exhibits very high electron mobility.

Accordingly, the region of the channel layer 103 facing the barrier layer 104 becomes a drift region. The drift region is a region formed in the channel layer 103 between the source and the drain, and is a region in which movement of a carrier occurs when a potential difference occurs between the source and the drain. The movement of the carrier in the drift region may be allowed/blocked and adjusted according to magnitude of voltage applied to the gate 110.

In FIG. 3A, the barrier layer 104 is illustrated as one layer, but the disclosure is not limited thereto. As such, according to another embodiment, the burrier layer 104 may be configured as a plurality of layers. The barrier layer 104 may include, for example, a plurality of layers having different energy bandgaps, and the plurality of layers may be provided such that the energy bandgap of a layer close to the channel layer 103 among the plurality of layers is larger.

The plurality of sources/drains 105a, 105b, 105c, and 105d may include conductive metals and the plurality of sources/drains 105a, 105b, 105c, and 105d may be spaced apart from each other on an upper surface of the barrier layer 104. In FIG. 2, the first to fourth four sources/drains 105a, 105b, 105c, and 105d are indicated by dotted lines. However, the number of the first to fourth sources/drains 105a, 105b, 105c, and 105d is not limited thereto, and may be selected as three or five or more.

The upper surface of the barrier layer 104 may have a square shape. The first to fourth sources/drains 105a, 105b, 105c and 105d may be provided in four quadrant regions on the upper surface of the barrier layer 104, respectively. For example, the first source/drain 105a, the second source/drain 105b, the third source/drain 105c, and the fourth source/drain 105d may be provided in a first quadrant regions, a second quadrant regions, a third quadrant regions, and a fourth quadrant region on the upper surface of the barrier layer 104, respectively. However, the disclosure is not limited thereto. As such, according to another embodiment, the upper surface of the barrier layer 104 may have a different shape.

In addition, as shown in FIG. 2, the first to fourth sources/drains 105a, 105b, 105c, and 105d may be provided avoiding a central region, a region near four vertices, and a region between two adjacent quadrant regions on the upper surface of the barrier layer 104. For example, the first source/drain 105a may be provided on the first quadrant region of the barrier layer 104. For example, the first source/drain 105a may be provided on the first quadrant region of the upper surface of the barrier layer 104 to cover a region excluding the central region of the upper surface of the barrier layer 104, a region near a vertex of the first quadrant region, a boundary region between the first quadrant region and the fourth quadrant region, and a boundary region between the first quadrant region and the second quadrant region. The second source/drain 105b may be provided on the second quadrant region. For example, the second source/drain 105b may be provided on the second quadrant region of the upper surface of the barrier layer 104 to cover a region excluding the central region of the upper surface of the barrier layer 104, a region near a vertex of the second quadrant region, a boundary region between the second quadrant region and the third quadrant region, and a boundary region between the second quadrant region and the first quadrant region. The third source/drain 105c may be provided on the third quadrant region. For example, the third source/drain 105c may be provided on the third quadrant region of the upper surface of the barrier layer 104 to cover a region excluding the central region of the upper surface of the barrier layer 104, a region near a vertex of the third quadrant region, a boundary region between the third quadrant region and the second quadrant region, and a boundary region between the third quadrant region and the fourth quadrant region. The fourth source/drain 105d may be provided on the fourth quadrant surface of the barrier layer 104. For example, the fourth source/drain 105d may be provided on the fourth quadrant of the upper surface of the barrier layer 104 to cover a region excluding the central region of the upper surface of the barrier layer 104, a region near a vertex of the fourth quadrant region, a boundary region between the fourth quadrant region and the first quadrant region, and a boundary region between the fourth quadrant region and the third quadrant region.

In addition, two adjacent sources/drains among the first to fourth sources/drains 105a, 105b, 105c, and 105d may have a symmetrical shape with respect to a boundary therebetween. For example, the first source/drain 105a and the fourth source/drain 105d may have a symmetrical shape with respect to a boundary between the first quadrant region and the fourth quadrant region. The first source/drain 105a and the second source/drain 105b may have a symmetrical shape with respect to a boundary between the first quadrant region and the second quadrant region. The second source/drain 105b and the third source/drain 105c may have a symmetrical shape with respect to a boundary between the second quadrant region and the third quadrant region. The third source/drain 105c and the fourth source/drain 105d may have a symmetrical shape with respect to a boundary between the third quadrant region and the fourth quadrant region. In addition, the first to fourth sources/drains 105a, 105b, 105c, and 105d may have a symmetrical shape with respect to the center of the semiconductor device 100 when viewed from the top.

The gate insulating layer 106 may be provided on the upper surface of the barrier layer 104. For example, the gate insulating layer 106 may be provided to cover the upper surface of the barrier layer 104. The gate insulating layer 106 may include, for example, at least one oxide material among SiO₂, HfOx, and Al₂O₃, but is not limited thereto. The gate insulating layer 106 may extend to cover a sidewall of the barrier layer 104, a sidewall of the channel layer 103, and a part of a sidewall of the buffer layer 102. In addition, the gate insulating layer 106 may be provided on sidewalls and upper surfaces of the first to fourth sources/drains 105a, 105b, 105c, and 105d. For example, the gate insulating layer 106 may be provided to cover sidewalls and upper surfaces of the first to fourth sources/drains 105a, 105b, 105c, and 105d. For electrical connection between the first to fourth conductor layers 107a, 107b, 107c, and 107d to be described below and the first to fourth sources/drains 105a, 105b, 105c, and 105d, the gate insulating layer 106 may be removed from partial regions of the first to fourth sources/drains 105a, 105b, 105c, and 105d, as shown in FIG. 3A. For example, partial regions of upper surfaces of the first to fourth sources/drains 105a, 105b, 105c, and 105d may be exposed without being covered by the gate insulating layer 106. However, the remaining regions of the upper surfaces of the first to fourth sources/drains 105a, 105b, 105c, and 105d may be covered by the gate insulating layer 106, as shown in FIG. 3B.

The gate 110 including a conductive metal may be provided on the gate insulating layer 106. As shown in FIG. 2, the gate 110 may be provided on an upper surface of the gate insulating layer 106 so as not to overlap the first to fourth sources/drains 105a, 105b, 105c, and 105d when viewed from the top. In addition, the gate 110 may include a center gate 110e provided in the center of the semiconductor device 100 or the center of the upper surface of the gate insulating layer 106, and first to fourth branch gates 110a, 110b, 110c, and 110d extending between two adjacent sources/drains among the first to fourth sources/drains 105a, 105b, 105c, and 105d. For example, the gate 110 may include the first branch gate 110a extending in a winding curved shape from the center gate 110e between the first source/drain 105a and the second source/drain 105b or along the boundary between the first quadrant region and the second quadrant region, the second branch gate 110b extending in a winding curved shape from the center gate 110e between the second source/drain 105b and the third source/drain 105c or along the boundary between the second quadrant region and the third quadrant region, the third branch gate 110c extending in a winding curved shape from the center gate 110e between the third source/drain 105c and the fourth source/drain region 105d or along the boundary between the third quadrant region and the fourth quadrant region, and the fourth branch gate 110d extending in a winding curved shape from the center gate 110e between the first source/drain 105a and the fourth source/drain 105d or along the boundary between the first quadrant region and the fourth quadrant region. A width of each of the first to fourth branch gates 110a, 110b, 110c, and 110d may be less than a width of the center gate 110e.

In an example case in which the first to fourth branch gates 110a, 110b, 110c, and 110d each have a winding curved shape, a surface area of each of the first to fourth branch gates 110a, 110b, 110c, and 110d may be wider than that of each of the first to fourth branch gates 110a, 110b, 110c, and 110d having a straight line shape. Accordingly, current injection efficiency may be improved, and thus, operating characteristics of the semiconductor device 100 may be improved. In addition, even though the semiconductor device 100 is manufactured in a small size with a side length of 100 μm or less, the operating characteristics of the semiconductor device 100 may not deteriorate.

Referring to FIGS. 2 and 3C, an end of each of the first to fourth branch gates 110a, 110b, 110c, and 110d of the gate 110 may protrude further laterally than sidewalls of the gate insulating layer 106, the barrier layer 104, and the channel layer 103 provided therebelow. For example, as shown in FIG. 3C, the end of the second branch gate 110b may extend along the surface of the gate insulating layer 106 to face the sidewall of the barrier layer 104 and the sidewall of the channel layer 103. Only the end of the second branch gate 110b is shown in the cross-sectional view of FIG. 3C, but ends of the first, third, and fourth branches gates 110a, 110c, and 110d may also extend along the surface of the gate insulating layer 106 to face the sidewall of the barrier layer 104 and the sidewall of the channel layer 103, similar to the second branch gate 110b.

According to an embodiment, the gate 110 including the first to fourth branch gates 110a, 110b, 110c, and 110d extends to the sidewall of the barrier layer 104 and the sidewall of the channel layer 103 without directly contacting the barrier layer 104, and thus, on/off control performance of the semiconductor device 100 by the gate 110 may be further enhanced.

In addition, the first to fourth conductor layers 107a, 107b, 107c, and 107d each including the conductive metal may be spaced apart from each other on the upper surface of the gate insulating layer 106. The first to fourth conductor layers 107a, 107b, 107c, and 107d may be provided in a region near the four vertices of the upper surface of the gate insulating layer 106 so as not to overlap the gate 110 including the center gate 110e and the first to fourth branch gates 110a, 110b, 110c, and 110d when viewed from the top. For example, the first conductor layer 107a may be provided in the vertex region of the first quadrant region on the upper surface of the gate insulating layer 106, the second conductor layer 107b may be provided in the vertex region of the second quadrant region on the upper surface of the gate insulating layer 106, the third conductor layer 107c may be provided in the vertex region of the third quadrant region on the upper surface of the gate insulating layer 106, and the fourth conductor layer 107d may be provided in the vertex region of the fourth quadrant region on the upper surface of the gate insulating layer 106.

The first to fourth conductive layers 107a, 107b, 107c and 107d may be electrically connected to the corresponding sources/drains among the first to fourth sources/drains 105a, 105b, 105c and 105d. For example, the first conductive layer 107a may be electrically connected to the first source/drain 105a, the second conductive layer 107b may be electrically connected to the second source/drain 105b, the third conductive layer 107c may be electrically connected to the third source/drain 105c, and the fourth conductive layer 107d may be electrically connected to the fourth source/drain 105d.

Referring to FIG. 3A, the fourth conductor layer 107d may extend to be in contact with a partial region of an upper surface of the fourth source/drain 105d exposed without being covered by the gate insulating layer 106, and the third conductor layer 107c may extend to be in contact with a partial region of an upper surface of the third source/drain 105c exposed without being covered by the gate insulating layer 106. Likewise, the first conductor layer 107a and the second conductor layer 107b may extend to be in contact with the first source/drain 105a and the second source/drain 105b, respectively. When viewed from the top, the first to fourth conductor layers 107a, 107b, 107c and 107d may overlap the corresponding sources/drains among the first to fourth sources/drains 105a, 105b, 105c and 105d in regions contacting the corresponding sources/drains.

The passivation layer 108 may include at least one oxide material among SiO₂, HfOx, and Al₂O₃, but is not limited thereto. The passivation layer 108 may be provided on the gate insulating layer 106, the gate 110, and the first to fourth conductive layers 107a, 107b, 107c, and 107d. For example, the passivation layer 108 may be provided to cover the gate insulating layer 106, the gate 110, and the first to fourth conductive layers 107a, 107b, 107c, and 107d. In addition, the passivation layer 108 may be provided on the barrier layer 104. For example, the passivation layer 108 may extend along the surface of the gate insulating layer 106 to cover the sidewall of the barrier layer 104, the sidewall of the channel layer 103, and a part of the sidewall of the buffer layer 102.

The first to fourth source/drain electrodes 109a, 109b, 109c, and 109d and the gate electrode 111 may be provided to penetrate the passivation layer 108 and be electrically connected to the first to fourth conductive layers 107a, 107b, 107c, and 107d and the gate 220 provided therebelow, respectively. For example, the first source/drain electrode 109a may be provided to penetrate the passivation layer 108 to be electrically connected to the first conductor layer 107a, the second source/drain electrode 109b may be provided to penetrate the passivation layer 108 to be electrically connected to the second conductor layer 107b, the third source/drain electrode 109c may be provided to penetrate the passivation layer 108 to be electrically connected to the third conductor layer 107c, and the fourth source/drain electrode 109d may be provided to penetrate the passivation layer 108 to be electrically connected to the fourth conductor layer 107d. The first to fourth sources/drains electrodes 109a, 109b, 109c, and 109d may be electrically connected to the corresponding sources/drains among the first to fourth sources/drains 105a, 105b, 105c, and 105d through the first to fourth conductor layers 107a, 107b, 107c, and 107d, respectively. In other words, the first source/drain electrode 109a may be electrically connected to the first source/drain 105a through the first conductor layer 107a, the second source/drain electrode 109b may be electrically connected to the second source/drain 105b through the second conductor layer 107b, the third source/drain electrode 109c may be electrically connected to the third source/drain 105c through the third conductor layer 107c, and the fourth source/drain electrode 109d may be electrically connected to the fourth source/drain 105d through the fourth conductor layer 107d. In addition, the gate electrode 111 may be provided to penetrate the passivation layer 108 and be electrically connected to the gate 110.

The semiconductor device 100 having the structure described above may be manufactured in a small size having a length of one side of 100 μm or less. The semiconductor device 100 having such a small size may be transferred in large quantities to another semiconductor substrate or heat dissipation substrate having a large area through wet transfer. For example, the semiconductor device 100 according to an embodiment may have a symmetrical electrode arrangement structure to be suitable for wet transfer.

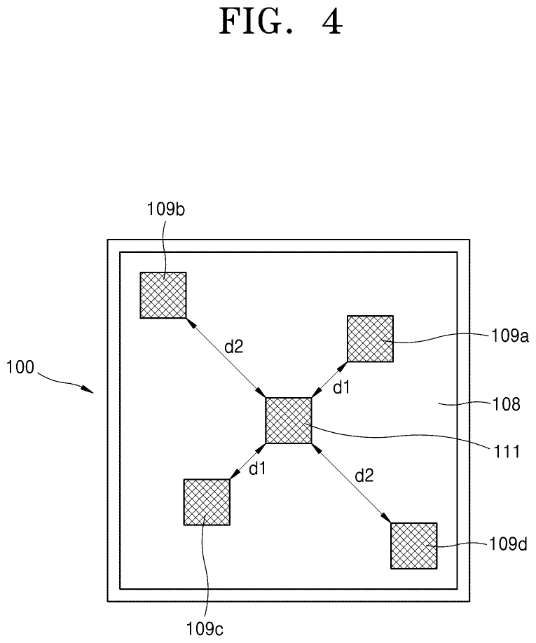

FIG. 4 is a plan view schematically illustrating an electrode arrangement structure of the semiconductor device 100 shown in FIG. 2 Referring to FIG. 4, the gate electrode 111 may be provided in the center of the semiconductor device 100 or the center of the passivation layer 108 when viewed from the top. In addition, two source/drain electrodes facing in a diagonal direction among the first to fourth sources/drains electrodes 109a, 109b, 109c, and 109d may be provided at the same distance from the center of the semiconductor device 100, the center of the passivation layer 108, or the center of the gate electrode 111 when viewed from the top. For example, the first source/drain electrode 109a and the third source/drain electrode 109c facing each other in a first diagonal direction may be provided at a first distance d1 from the center of the semiconductor device 100, the center of the passivation layer 108, or the center of the gate electrode 111, and the second source/drain electrode 109b and the fourth source/drain electrode 109d facing each other in a second diagonal direction crossing the first diagonal direction may be provided at a second distance d2 from the center of the semiconductor device 100, the center of the passivation layer 108, or the center of the gate electrode 111.

Meanwhile, source/drain electrodes that do not face each other in the diagonal direction among the first to fourth sources/drains electrodes 109a, 109b, 109c, and 109d may be provided at different distances from the center of the semiconductor device 100, the center of the passivation layer 108, or the center of the gate electrode 111. For example, the first distance d1 from the center of the semiconductor device 100, the center of the passivation layer 108, or the center of the gate electrode 111 to the first source/drain electrode 109a or the third source/drain electrode 109c may be different from the second distance d2 from the center of the semiconductor device 100, the center of the passivation layer 108, or the center of the gate electrode 111 to the second source/drain electrode 109b or the fourth source/drain electrode 109d. In this regard, it may be seen that the first to fourth sources/drains electrodes 109a, 109b, 109c, and 109d and the gate electrode 111 have a symmetrical arrangement structure in the diagonal direction with respect to the center of the semiconductor device 100, the center of the passivation layer 108, or the center of the gate electrode 111.

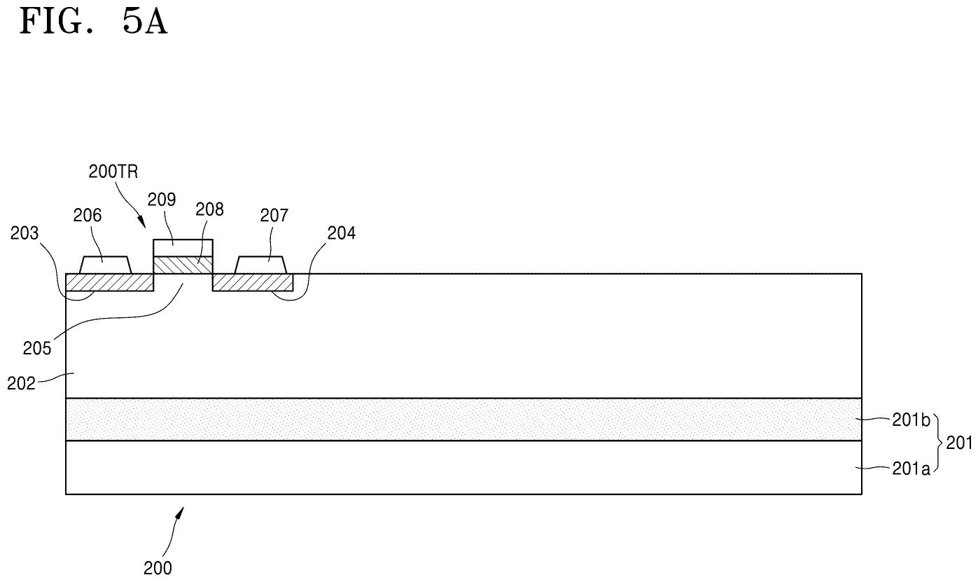

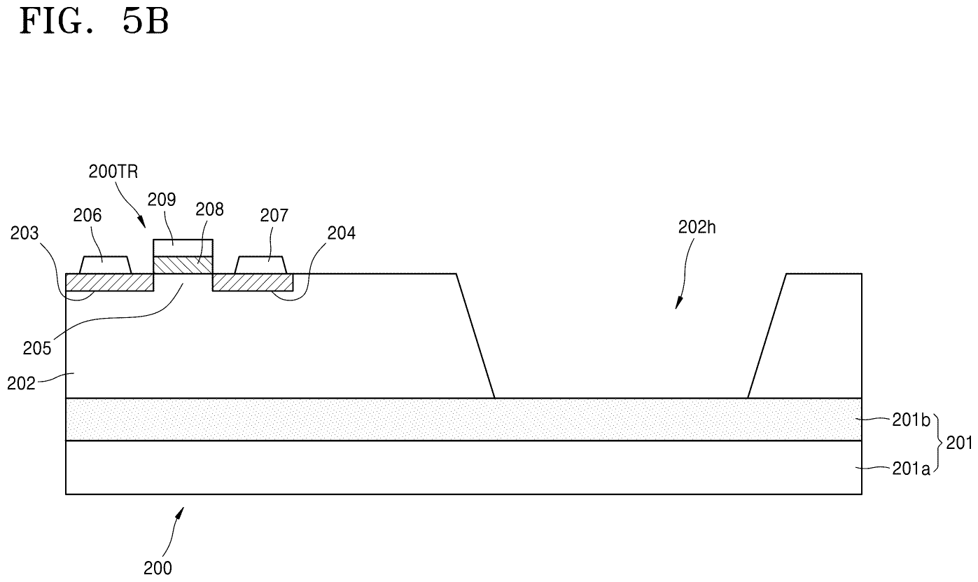

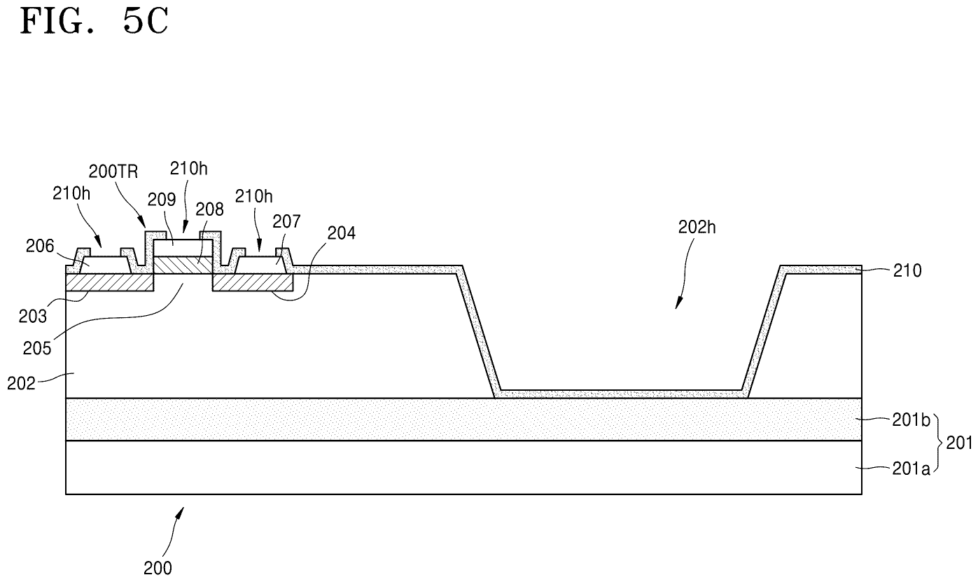

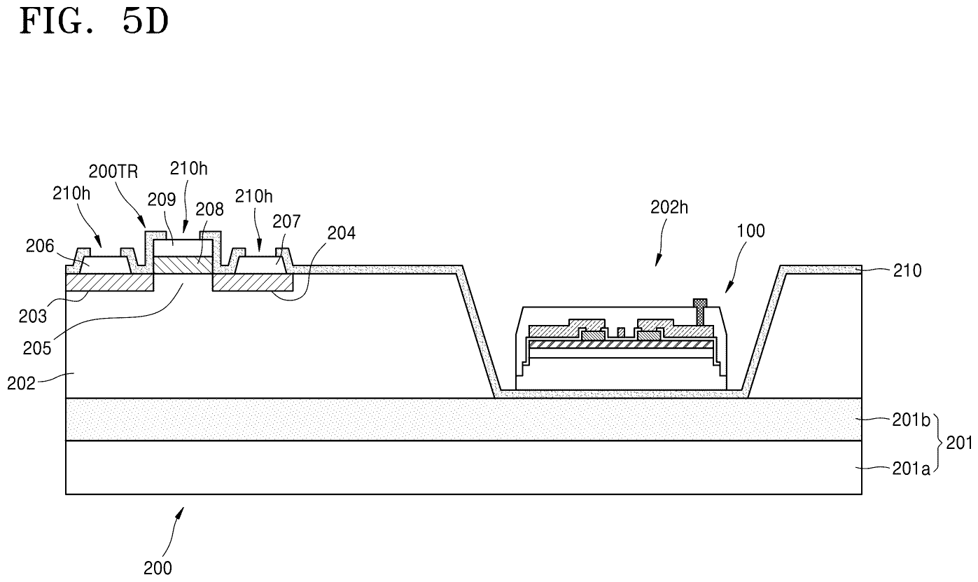

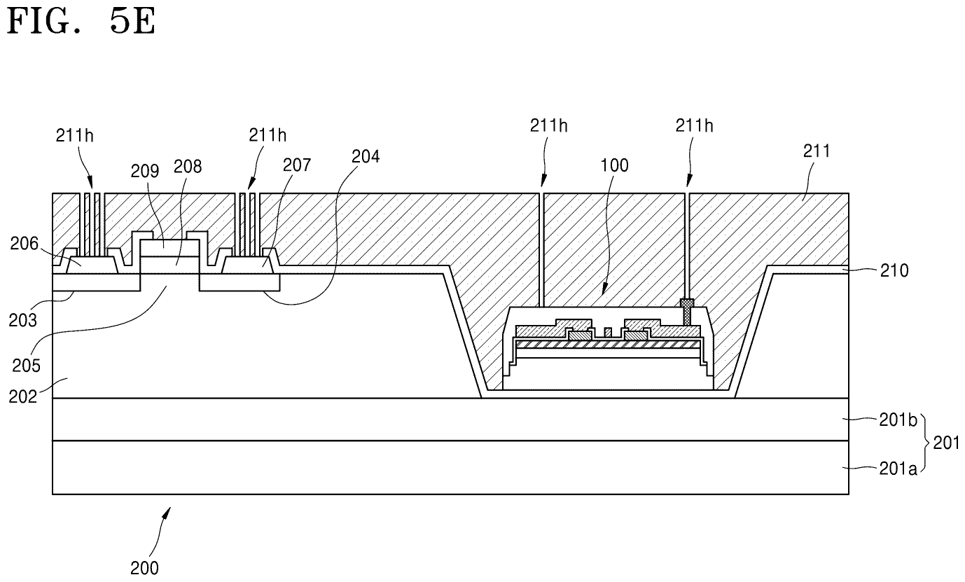

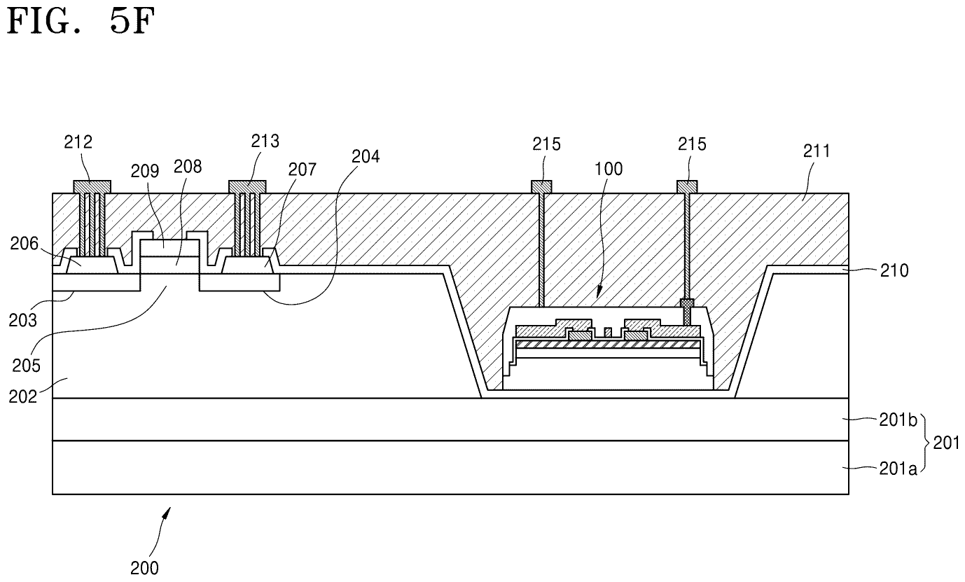

FIGS. 5A to 5F illustrate a process of manufacturing the power amplifier 200 by integrating the semiconductor device 100 shown in FIG. 2 on heterogeneous semiconductor substrates.

Referring to FIG. 5A, the power amplifier 200 may include a first substrate 201, a second substrate 202 provided on the first substrate 201, and a third transistor 200TR on the second substrate 202. For example, the second substrate 202 is provided on an upper surface of the first substrate 201. The first substrate 201 may be a silicon-on-insulator (SOI) substrate including a semiconductor layer 201a and an insulating layer 201b provided on an upper surface of the semiconductor layer 201a. The second substrate 202 may include a first semiconductor material. For example, the first semiconductor material may include a group IV semiconductor material such as silicon and germanium. The second substrate 202 may be, for example, a group IV semiconductor substrate including a group IV semiconductor material such as silicon or germanium. The insulating layer 201b may include, for example, silicon oxide (SiO₂) or silicon nitride (SiN). FIG. 5A illustrates that the power amplifier 200 is formed on the SOI substrate, but the power amplifier 200 may be manufactured using a bulk silicon substrate instead of the SOI substrate. For example, the power amplifier 200 may include only the second substrate 202 without the first substrate 201.

The third transistor 200TR may be a metal-oxide-semiconductor field-effect transistor (MOSFET). For example, the third transistor 200TR may include a source region 203 provided on the second substrate 202, a drain region 204 provided on the second substrate 202 to be separated from the source region 203, a channel layer 205 provided between the source region 203 and the drain region 204, a gate insulating layer 208 provided on an upper surface of the channel layer 205, a gate electrode 209 provided on an upper surface of the gate insulating layer 208, a source electrode 206 provided on an upper surface of the source region 203, and a drain electrode 207 provided on an upper surface of the drain region 204. The source region 203 and the drain region 204 may be formed by doping an upper portion of the second substrate 202. Therefore, the third transistor 200TR may be a MOSFET provided on a group IV semiconductor substrate and including a group IV semiconductor material.

Referring to FIG. 5B, a groove 202h may be formed on the second substrate 202. For example, a groove 202h may be formed by partially etching the upper surface of the second substrate 202 adjacent to the third transistor 200TR. In this case, the insulating layer 201b of the first substrate 201 may function as an etching stop layer. An upper surface of the insulating layer 201b of the first substrate 201 may be partially exposed through the groove 202h.

Referring to FIG. 5C, the insulating layer 210 may be provided on the third transistor 200TR, the second substrate 202, and the groove 202h. For example, the first substrate 201 may be further provided on first substrate 201. For example, the insulating layer 210 may be formed to cover the third transistor 200TR, the upper surface of the second substrate 202, and an inner wall and a bottom surface of the groove 202h. The insulating layer 210 may include an insulating material having hydrophilicity. The insulating layer 210 may be formed by depositing at least one oxide material of, for example, SiO₂, HfOx and Al₂O₃ with a uniform thickness. The inner wall of the groove 202h may be inside of the second substrate 202 exposed by the groove 202h, and the bottom surface thereof may be the upper surface of the insulating layer 201b exposed by the groove 202h.

In addition, a part of the insulating layer 210 may be etched so that the upper surfaces of the source electrode 206, the drain electrode 207, and the gate electrode 209 of the third transistor 200TR are partially exposed. For example, a plurality of openings 210h completely penetrating the insulating layer 210 may be formed by etching a part of the insulating layer 210 covering the source electrode 206, the drain electrode 207, and the gate electrode 209.

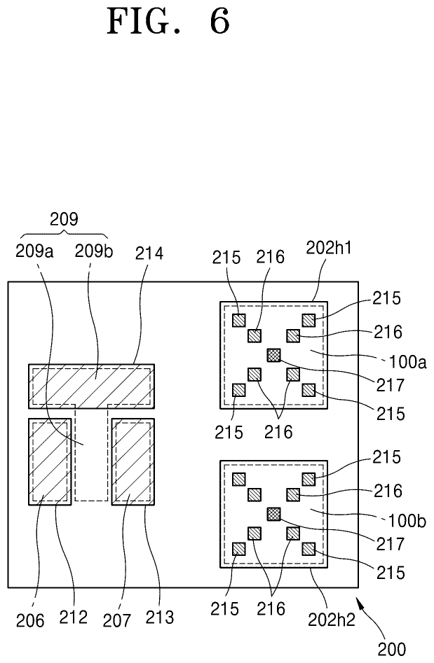

Referring to FIG. 5D, the semiconductor device 100 shown in FIG. 2 may be transferred into the groove 202h. For example, the semiconductor device 100 shown in FIG. 2 may be transferred into the groove 202h by using a wet transfer method to be described below. At this time, because FIGS. 5A to 5F are cross-sectional views, one semiconductor device 100 is provided in one groove 202h, but as shown in FIG. 6, the first transistor 100a may be provided in a first groove 202h1, and the second transistor 100b may be provided in a second groove 202h2. Hereinafter, the groove 202h of FIGS. 5A to 5F may be referred to as the first groove 202h1 or the second groove 202h2, and the semiconductor device 100 may be referred to as a first transistor 100a or a second transistor 100b.

The semiconductor device 100 may include a second semiconductor material different from the first semiconductor material. For example, the second semiconductor material may include a group III-V semiconductor material such as AlN, GaN, AlGaN, InGaN, AlInN, AlGaInN, etc. Before wet transfer, the substrate 101 may be previously removed from the semiconductor device 100 shown in FIG. 2 by a chemical lift-off or laser lift-off method. Then, a lower surface of the semiconductor device 100 becomes a lower surface of the buffer layer 102. The lower surface of the buffer layer 102 separated by the chemical lift-off or laser lift-off method may be very smooth and flat, and may have hydrophilic properties. On the other hand, an upper surface of the semiconductor device 100 in which the gate electrode 111 and the first to fourth sources/drains electrodes 109a, 109b, 109c, and 109d are formed is hydrophobic. Therefore, in an example case in which the buffer layer 102 of the semiconductor device 100 faces the bottom surface of the groove 202h during a wet transfer process, the semiconductor device 100 may be easily seated in the groove 202h. On the other hand, in an example case in which the gate electrode 111 and the first to fourth sources/drains electrodes 109a, 109b, 109c, and 109d face the bottom surface of the groove 202h, the semiconductor device 100 may be easily separated from the groove 202h. Therefore, the semiconductor device 100 may be transferred so that the gate electrode 111 and the first to fourth sources/drains electrodes 109a, 109b, 109c, and 109d of the semiconductor device 100 face outside of the groove 202h.

In FIGS. 5A to 5D, the groove 202h is formed in the second substrate 202 of the power amplifier 200, and the semiconductor device 100 shown in FIG. 2 is directly transferred to the power amplifier 200. However, after the semiconductor device 100 is first aligned on a separate transfer substrate, the semiconductor device 100 may be transferred to the power amplifier 200 by using a transfer substrate.

Referring to FIG. 5E, the passivation layer 211 may be formed on the third transistor 200TR and the semiconductor device 100. For example, the passivation layer 211 may be formed to cover the third transistor 200TR and the semiconductor device 100. The passivation layer 211 may be formed to completely fill inside of the groove 202h. Then, a part of the passivation layer 211 may be etched so that upper surfaces of the source electrode 206, the drain electrode 207, and the gate electrode 209 of the third transistor 200TR and upper surfaces of the gate electrode 111 and the first to fourth sources/drains electrodes 109a, 109b, 109c, and 109d of the semiconductor device 100 are exposed. For example, a plurality of openings 211h completely penetrating the passivation layer 211 may be formed by etching a part of the passivation layer 211 covering the source electrode 206, the drain electrode 207, and the gate electrode 209 of the third transistor 200TR, and the gate electrode 111 and the first to fourth sources/drains electrodes 109a, 109b, 109c, and 109d of the semiconductor device 100. The openings 211h exposing the gate electrode 209 of the third transistor 200TR are not shown in FIG. 5E, but the openings 211h exposing the gate electrode 209 of the third transistor 200TR may be formed at a position different from the cross-section shown in FIG. 5E.

Referring to FIG. 5F, first, second, fourth, and fifth electrode pads 212, 213, 215, and 216 may be formed by filling each of the plurality of openings 211h of the passivation layer 211 with a conductive metal. An electrode pad electrically connected to the gate electrode 209 of the third transistor 200TR is not shown in FIG. 5F, but an electrode pad electrically connected to the gate electrode 209 of the third transistor 200TR may be formed at a position different from the cross-section shown in FIG. 5F. The first, second, fourth, and fifth electrode pads 212, 213, 215, and 216 may protrude above the upper surface of the passivation layer 211 and extend laterally along the upper surface of the passivation layer 211.

FIG. 6 is a plan view illustrating arrangement of a plurality of electrode pads included in the resulting power amplifier 200. At this time, positions where the first transistor 100a and the second transistor 100b are formed are for convenience of explanation, and may be different from those shown in FIG. 6 according to manufacturing needs.

Referring to FIG. 6, the power amplifier 200 may include the first electrode pad 212 electrically connected to the source electrode 206 of the third transistor 200TR, the second electrode pad 213 electrically connected to the drain electrode 207, and a third electrode pad 214 electrically connected to the gate electrode 209. As indicated by dotted lines in the plan view of FIG. 6, the gate electrode 209 of the third transistor 200TR may have a first portion 209a extending in a first direction between the source electrode 206 and the drain electrode 207 and a second portion 209b extending in a direction perpendicular to the first direction. Therefore, the gate electrode 209 of the third transistor 200TR may have a T shape. The third electrode pad 214 may be provided to be in contact with the second portion 209b of the gate electrode 209.

The power amplifier 200 may further include the plurality of fifth electrode pads 216 electrically connected to one of the first source/drain electrode 109a and the third source/drain electrode 109c of the semiconductor device 100, the plurality of fourth electrode pads 215 electrically connected to one of the second source/drain electrode 109b and the fourth source/drain electrode 109d of the semiconductor device 100, and a sixth electrode pad 217 electrically connected to the gate electrode 111 of the semiconductor device 100. For example, the four fourth electrode pads 215 may be located at the second distance d2 in a diagonal direction from the center of the sixth electrode pad 217, and the four fifth electrode pads 216 may be located at the first distance d1 in the diagonal direction from the center of the sixth electrode pad 217. Therefore, regardless of a rotation direction of the semiconductor device 100 during a wet transfer process, the first source/drain electrode 109a and the third source/drain electrode 109c of the semiconductor device 100 may be electrically connected to any one of the four fifth electrode pads 216, and the second source/drain electrode 109b and the fourth source/drain electrode 109d may be electrically connected to any one of the four fourth electrode pads 215.

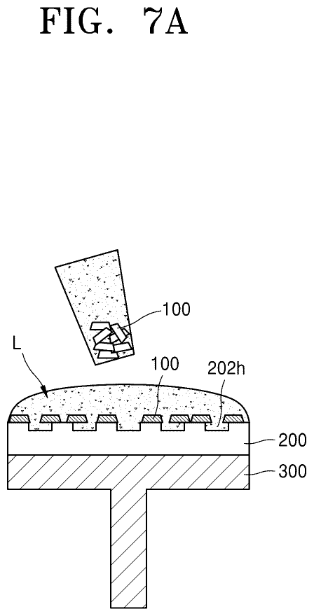

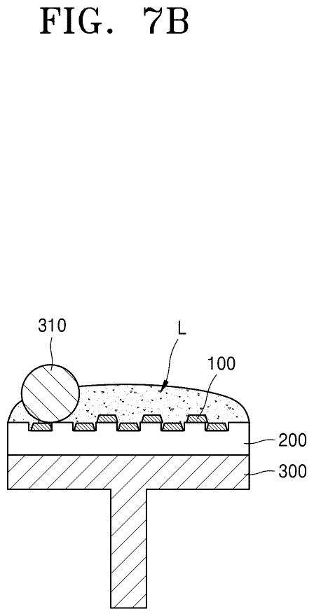

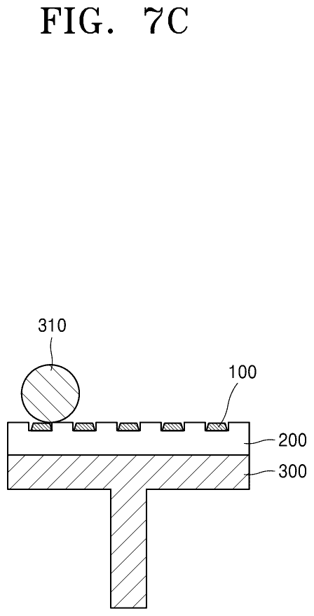

FIGS. 7A to 7C illustrate a process of wet transferring the semiconductor device 200 shown in FIG. 2 onto heterogeneous semiconductor substrates.

Referring to FIG. 7A, the power amplifier 200 on which the semiconductor device 100 is to be transferred may be mounted on a transfer head 300. The power amplifier 200 may include the plurality of grooves 202h in which the plurality of semiconductor devices 100 are to be mounted, respectively. After the plurality of semiconductor devices 100 supply liquid L to the grooves 202h of the power amplifier 200, the plurality of semiconductor devices 100 may be directly sprayed on the power amplifier 200 or may be supplied on the power amplifier 200 while being included in the liquid L.

The liquid L supplied to the groove 202h may be any kind of liquid as long as it does not corrode or damage the semiconductor device 100 and the power amplifier 200. The liquid L may be supplied to the grooves 202h in various ways, including but not limited to, a spray method, a dispensing method, an inkjet dot method, and a method of flowing the liquid L to the power amplifier 200. The liquid L may include, for example, one or a combination of groups including water, ethanol, alcohol, polyol, ketone, halocarbon, acetone, flux, and organic solvent. The organic solvent may include, for example, isopropyl alcohol (IPA). The supply amount of the liquid L may be in various ways adjusted to fit the grooves 202h or to overflow from the grooves 202h.

The plurality of semiconductor devices 100 may be directly sprayed on the power amplifier 200 without other liquids, or may be supplied onto the power amplifier 200 while included in the liquid L such as a suspension. As a method of supplying the semiconductor device 100 included in the suspension, a spray method, a dispensing method of dripping liquid, an inkjet dot method of discharging liquid in drops like a printing method, a method of flowing the suspension to the power amplifier 200, etc. may be used in various ways.

Referring to FIG. 7B, after supplying the plurality of semiconductor devices 100 onto the power amplifier 200, scanning for aligning the plurality of semiconductor devices 100 may be performed. For example, an absorbent 310 may scan an upper surface of the power amplifier 200. According to scanning, the absorbent 310 may contact the power amplifier 200, move the semiconductor device 100 into the grooves 202h while passing through the plurality of grooves 202h, and absorb the liquid L in the grooves 202h. The absorbent 310 is sufficient as long as it is a material capable of absorbing the liquid L, and its shape or structure is not limited. The absorbent 310 may include, for example, fabric, tissue, polyester fiber, paper or wiper.

The absorbent 310 may scan the power amplifier 200 while pressing the power amplifier 200 at an appropriate pressure. Scanning may be performed in various ways, including but not limited to, a sliding method, a rotating method, a translating exercise method, a reciprocating exercise method, a rolling method, a spinning method, and/or a rubbing method of the absorbent 310, and may include both a regular method and an irregular method. Scanning may be performed by moving the transfer head 300 instead of moving the absorbent 310. Scanning may be performed through cooperation between the absorbent 310 and the transfer head 300.

Referring to FIG. 7C, after the absorbent 310 scans the power amplifier 200, the semiconductor device 100 that does not enter the grooves 202h and remains on the upper surface of the power amplifier 200 may be recovered. The above-described processes may be repeated until the semiconductor device 100 is seated in all the grooves 202h. As described above, a large number of semiconductor devices 100 may be aligned in the power amplifier 200 of a large area by using the wet transfer method.

As described above, the lower surface of the buffer layer 102 of the semiconductor device 100 is very smooth and flat and has hydrophilicity. In addition, the bottom surface of the groove 202h is also very smooth and flat, and may have hydrophilicity. Therefore, in an example case in which the buffer layer 102 of the semiconductor device 100 faces the bottom surfaces of the grooves 202h during the wet transfer process shown in FIGS. 7A to 7C, the semiconductor device 100 may be easily seated in and fixed to the grooves 202h by the van der Waals force. On the other hand, in an example case in which the first to fourth sources/drains electrodes 109a, 109b, 109c, and 109d face the bottom surfaces of the grooves 202h, the semiconductor device 100 may be easily separated from the groove 202h during a scanning process. When the scanning process is repeated, only the semiconductor device 100 in which the buffer layer 102 is provided to face the bottom surfaces of the grooves 202h remains in the groove 202h. The remaining semiconductor devices 100 may be recovered from the upper surface of the power amplifier 200.

After the process shown in FIG. 5F, wirings for electrical connection with the semiconductor device 100 in the power amplifier 200 may be further formed.

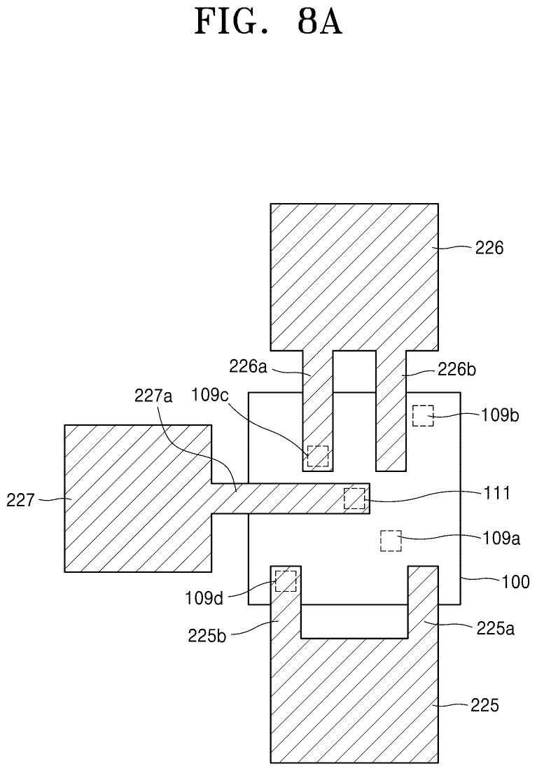

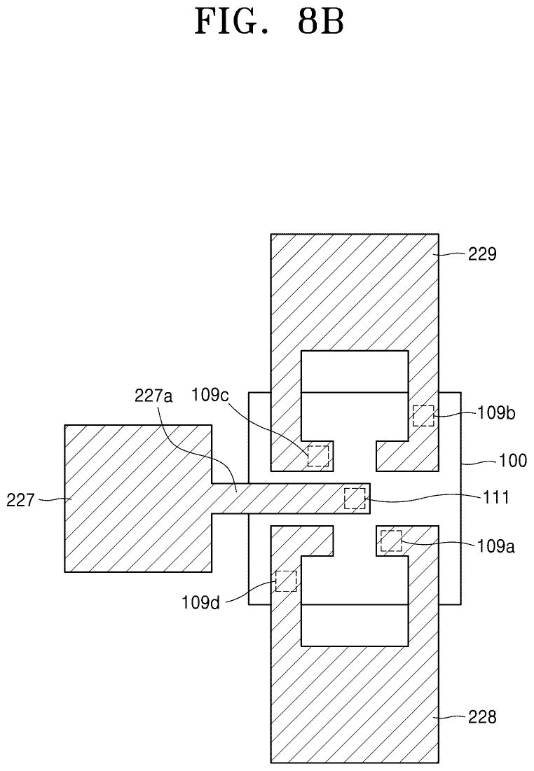

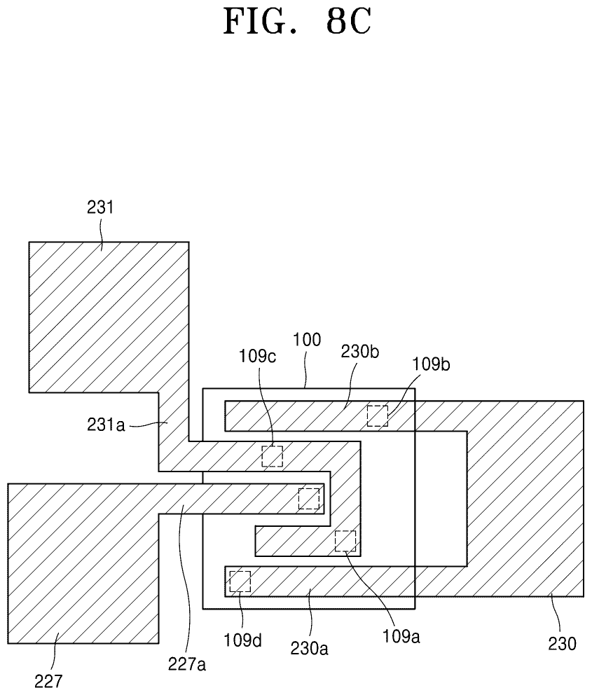

FIGS. 8A to 8C illustrate various wiring forms for electrical connection with the semiconductor device 100 shown in FIG. 2 in the power amplifier 200 according to an embodiment. FIGS. 8A to 8C schematically illustrate resultant connections between the first to fourth sources/drains electrodes 109a, 109b, 109c, and 109d of the semiconductor device 100, and the gate electrode 111, and wirings. However, in reality, the wirings shown in FIGS. 8A to 8C may directly contact the fourth to sixth electrode pads 215, 216, and 217 shown in FIG. 6, and may be indirectly connected to the first to fourth sources/drains electrodes 109a, 109b, 109c, and 109d and the gate electrode 111.

Referring to FIG. 8A, the power amplifier 200 may include a first wiring 225, a second wiring 226, and a third wiring 227. The first to third wirings 225, 226, and 227 may be electrically connected to the semiconductor device 100 so that the semiconductor device 100 operates normally regardless of a rotation direction of the semiconductor device 100 during a transfer process.

For example, the first wiring 225 and the second wiring 226 may be provided on opposite side surfaces of the semiconductor device 100. The first wiring 225 may include two arms 225a and 225b extending in a straight line toward the semiconductor device 100 to be connected to any one of the second source/drain electrode 109b and the fourth source/drain electrode 109d located at the second distance d2 from the center of the semiconductor device 100. The second wiring 226 may include two arms 226a and 226b extending in the straight line toward the semiconductor device 100 to be connected to any one of the first source/drain electrode 109a and the third source/drain electrode 109c located at the first distance d1 from the center of the semiconductor device 100. In this case, a space between the two arms 225a and 225b of the first wiring 225 may be greater than a space between the two arms 226a and 226b of the second wiring 226.

The third wiring 227 may be provided on one of two side surfaces of the semiconductor device 100 that are different from side surfaces on which the first wiring 225 and the second wiring 226 are not provided. The third wiring 227 may include one arm 227a extending in the straight line toward the center of the semiconductor device 100 to be connected to the gate electrode 111. An extension direction of the arm 227a of the third wiring 227 may be perpendicular to extension directions of the arm 225a and 225b of the first wiring 225 and the arm 226a and 226b of the second wiring 226.

Referring to FIG. 8B, the power amplifier 200 may include a first wiring 228, a second wiring 229, and a third wiring 227. The first wiring 228 and the second wiring 229 are provided on opposite side surfaces of the semiconductor device 100 and may have the same shape. The first wiring 228 may include two arms 228a and 228b bent to be connected to any two source/drain electrodes adjacent to each other among the first to fourth sources/drains electrodes 109a, 109b, 109c, and 109d, and the second wiring 229 may include two arms 229a and 229b bent to be connected to the remaining two source/drain electrodes adjacent to each other without being connected to the first wiring 228 among the first to fourth sources/drains electrodes 109a, 109b, 109c, and 109d. For example, the two arms 228a and 228b of the first wiring 228 and the two arms 229a and 229b of the second wiring 229 may extend in the straight line toward the semiconductor device 100 to be connected to any one of the second source/drain electrode 109b and the fourth source/drain electrode 109d located at the second distance d2 from the center of the semiconductor device 100, and then may have shapes bent by 90 degrees to be connected to any one of the first source/drain electrode 109a and the third source/drain electrode 109c located at the first distance d1 from the center of the semiconductor device 100.

Referring to FIG. 8C, the power amplifier 200 may include a first wiring 230, a second wiring 231, and the third wiring 227. The first wiring 230 may include two arms 230a and 230b extending in the straight line toward the center of the semiconductor device 100 so as to be connected to both the second source/drain electrode 109b and the fourth source/drain electrode 109d located at the second distance d2 from the center of the semiconductor device 100. The second wiring 231 may include one arm 231a bent to be connected to both the first source/drain electrode 109a and the third source/drain electrode 109c located at the first distance d1 from the center of the semiconductor device 100. For example, the arm 231a of the second wiring 231 may be bent twice by 90 degrees to surround three surfaces of the arm 227a of the third wiring 227 between the two arms 230a and 230b of the first wiring 230.

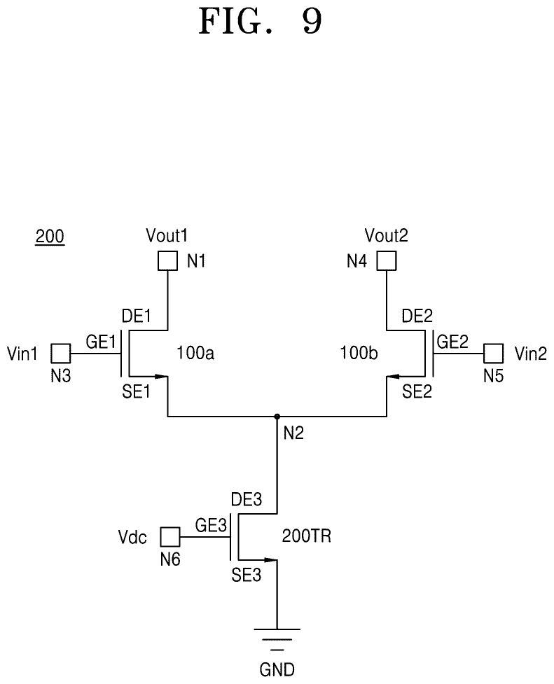

FIG. 9 is a circuit diagram illustrating the power amplifier 200 according to an embodiment.

Referring to FIG. 9, the power amplifier 200 according to an embodiment may include the first transistor 100a, the second transistor 100b, and the third transistor 200TR. The power amplifier 200 may be configured as an amplifier having a differential structure in which the first transistor 100a and the second transistor 100b are connected to each other in parallel and connected to the third transistor 200TR in series.

The first transistor 100a may include a drain DE1 connected between a first output node N1 and a common node N2, a source SE1 connected to the common node N2, and a gate GE1 connected to a first input node N3. The second transistor 100b may include a drain DE2 connected between a second output node N4 and the common node N2, a source SE2 connected to the common node N2, and a gate GE2 connected to a second input node N5. The third transistor 200TR may include a drain DE3 connected between the common node N2 and ground GND, a source SE3 connected to the ground GND, and a gate GE3 connected to a first switch node N6.

According to an embodiment, the drain electrode 207 of FIG. 6 of the third transistor 200TR may be electrically connected to any two of the first to fourth sources/drains electrodes 109a, 109b, 109c, and 109d of FIG. 4 of the first transistor 100a (or the semiconductor device 100), and any two of the first to fourth sources/drains electrodes 109a, 109b, 109c, and 109d of the second transistor 100b (or the semiconductor device 100) of FIG. 4. In addition, the gate electrode 209 of FIG. 6 of the third transistor 200TR may be connected to a separate first DC voltage source Vdc.

The remaining two of the first to fourth sources/drains electrodes 109a, 109b, 109c, and 109d of the first transistor 100a (or the semiconductor device 100) that are not connected to the drain electrode 207 of FIG. 6 of the third transistor 200TR may be connected to the first output node N1. At this time, the first output node N1 may function as a first output terminal from which a first differential output signal Vout1 is output. In addition, the gate electrode 111 of FIG. 4 of the first transistor 100a (or the semiconductor device 100) may be connected to the first input node N3. At this time, the first input node N3 may function as a first input terminal to which a first differential input signal Vin1 of alternating current (AC) is input.

Likewise, the remaining two of the first to fourth sources/drains electrodes 109a, 109b, 109c, and 109d of the second transistor 100b (or the semiconductor device 100) that are not connected to the drain electrode 207 of FIG. 6 of the third transistor 200TR may be connected to the second output node N4. In addition, the gate electrode 111 of FIG. 4 of the second transistor 100b (or the semiconductor device 100) may be connected to the second input node N5. At this time, the second input node N5 may function as a first input terminal to which a second differential input signal Vin2 of AC is input.

As described above, the first transistor 100a and the second transistor 100b may each include a group III-V semiconductor material and may be a depletion mode (d-mode) HEMT operating normally-on. Because a threshold voltage of the first transistor 100a and a threshold voltage of the second transistor 100b have negative values, the first transistor 100a and the second transistor 100b generally have normally-on characteristics. In other words, even if no voltage is applied to the gates GE1 and GE2 of the first transistor 100a and the second transistor 100b, current flows through a channel between two adjacent sources/drains, and when the voltage is applied to the gates GE1 and GE2, the first transistor 100a and the second transistor 100b are turned off.

The third transistor 200TR may be a MOSFET including a group IV semiconductor material. For example, the third transistor 200TR may be an n-type MOSFET, and a threshold voltage of the third transistor 200TR may have a positive value.

As shown in FIG. 9, in an example case in which the first transistor 100a and the second transistor 100b connected in parallel are connected in series with the third transistor 200TR, the power amplifier 200 may have normally-off characteristics.

In this case, when an equivalent circuit of the power amplifier 200 shown in FIG. 9 is analyzed according to analysis of a large signal that considers both an AC component and a DC component of the signal, the sum of current flowing through drain-source of each of the first transistor 100a and the second transistor 100b becomes drain-source current of the third transistor 200TR. Therefore, a voltage drop occurs between the drain DE3 and the source SE3 of the third transistor 200TR, and voltages of the sources SE1 and SE2 of the first transistor 100a and the second transistor 100b are respectively higher than the voltages of the gates GE1 and GE2, and thus, a problem of negative threshold voltages of the first transistor 100a and the second transistor 100b may be solved. In other words, in an example case in which DC voltage greater than or equal to the threshold voltage is applied to the gate GE3 of the third transistor 200TR from the first DC voltage source Vdc, current may flow between the first output node N1 and the ground GND, and between the second output node N4 and the ground GND.

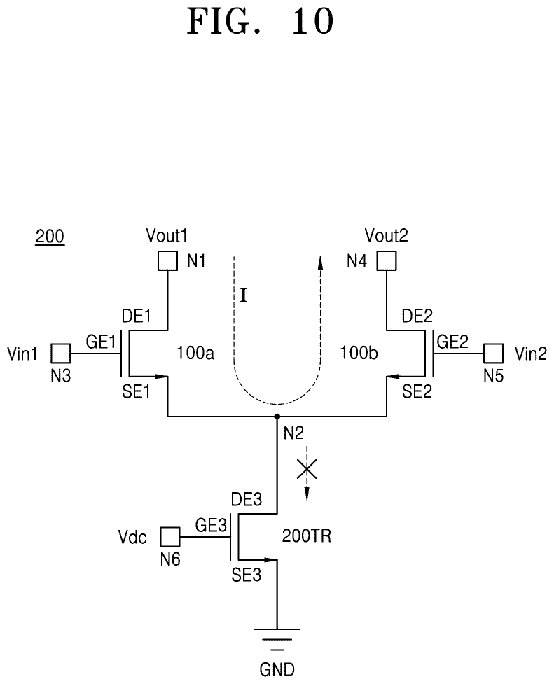

FIG. 10 is a diagram for analyzing an equivalent circuit of the power amplifier 200 through analysis of a small signal.

Referring to FIG. 10, unlike analysis of a large signal that considers both an AC component and a DC component of the signal, analysis of the small signal is an analysis technique that considers only the AC component of the signal. In a differential amplifier circuit, an AC component mainly serves to operate a plurality of transistors normally, while the AC component corresponds to a differential input signal that a differential amplifier wants to amplify.

When the equivalent circuit of the power amplifier 200 shown in FIG. 10 is analyzed through analysis of the small signal to obtain a voltage gain with respect to a differential input signal (i.e., Vin1-Vin2), the first transistor 100a and the second transistor 100b may form a differential amplification stage, the first differential input signal Vin1 may be input to the gate GE1 of the first transistor 100a, the second differential input signal Vin2 may be input to the gate GE2 of the second transistor 100b, the first differential output signal Vout1 may be output to the drain DE1 of the first transistor 100a, and the second differential output signal Vout2 may be output to the drain DE2 of the second transistor 100b. That is, the voltage gain may correspond to a value obtained by dividing a differential output signal (i.e., Vout1-Vout2) by the differential input signal (i.e., Vin1-Vin2).

At this time, because current of the AC component flows from the drain DE1 to the source SE1 at an end of the first transistor 100a, and the current of the AC component flows from the source SE2 to the drain DE2 at an end of the second transistor 100b, the current of the AC component may generally start at the first output node N1 and flow in a “U” shape toward the second output node N4 via the common node N2.

Meanwhile, the common node N2 in which the source SE1 of the first transistor 100a and the source SE2 of the second transistor 100b are connected to each other maintains a constant potential with respect to changes in input and output, and may function as a virtual ground. Therefore, because the common node N2 is the virtual ground at a frequency of the differential signal that the power amplifier 200 wants to amplify, a noise component of the signal may not ideally exist. For example, an AC component different from the differential signal may not ideally exist. Therefore, even in an example case in which the third transistor 200TR is connected to the common node N2 in which the virtual ground is formed, the third transistor 200TR may not deteriorate signal amplification performance of the entire power amplifier 200.

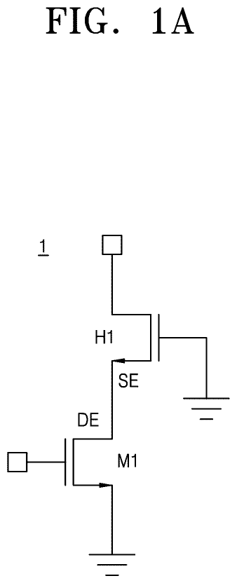

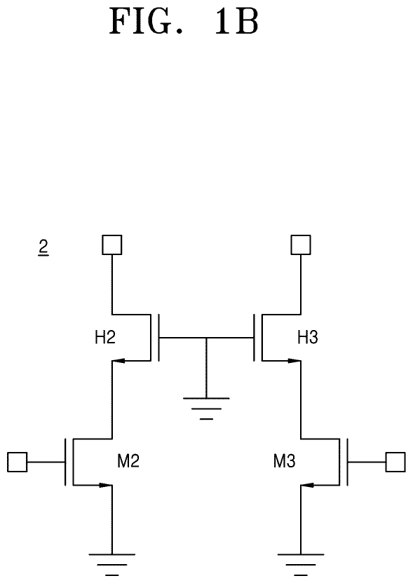

Upon comparing the power amplifier 2 of the related art shown in FIG. 1B with the power amplifier 200 shown in FIG. 9 according to the disclosure, from a structural point of view, the power amplifier 200 according to the disclosure has the advantage of reducing the entire circuit area because only one silicon MOSFET is omitted.

Considering the size of silicon MOSFET (e.g., M2, M3, or 200TR) in order to compare the power amplifier 2 of the related art with the power amplifier 200 according to the disclosure from a performance point of view, because the silicon MOSFET (e.g., M2, M3, or 200TR) has low current driving capability compared to a GaN HEMT (e.g., H2, H3, 100a, or 100b), to overcome this, a gate width of the silicon MOSFET (e.g., M2, M3, or 200TR) needs to be secured with a sufficient size. In this case, the current driving capability of the silicon MOSFET (e.g., M2, M3, or 200TR) may be secured, but the parasitic capacitance of gates of the silicon MOSFETs (e.g., M2, M3, and 200TR) may also increase. At this time, in the case of power amplifier 2 of the related art, because the AC component of the input signal is applied to a gate of the silicon MOSFET (e.g., M2 or M3) having a large parasitic capacitance, there was a problem that a power gain of the entire amplifier stage decreases.

On the other hand, in the structure of the power amplifier 200 according to the disclosure, because the AC component of the input signal is applied to the gate of the GaN HEMT (e.g., 100a or 100b) and DC voltage (e.g., Vdc) is applied to the gate of the silicon MOSFET (e.g., 200TR), the increased gate parasitic capacitance of the silicon MOSFET (e.g., 200TR) with a wide gate width may not deteriorate the power gain of the entire circuit.

As a result, the structure of the power amplifier 200 according to the disclosure may reduce production costs and achieve miniaturization by reducing the number of silicon MOSFETs compared to the power amplifier 2 of the related art.

As described above, the structure of the power amplifier 200 according to the disclosure has the advantage in that a region of the silicon MOSFET (e.g., 200TR) connected to the GaN HEMT (e.g., 100a or 100b) is freely modified according to the required function and performance of the circuit because the virtual ground is formed in a source (e.g., SE1 or SE2) of the GaN HEMT (e.g., 100a or 100b).

Hereinafter, other embodiments will be described. In the following embodiment, descriptions of the same elements as those of the previously described embodiments will be omitted or simplified, and differences will be mainly described.

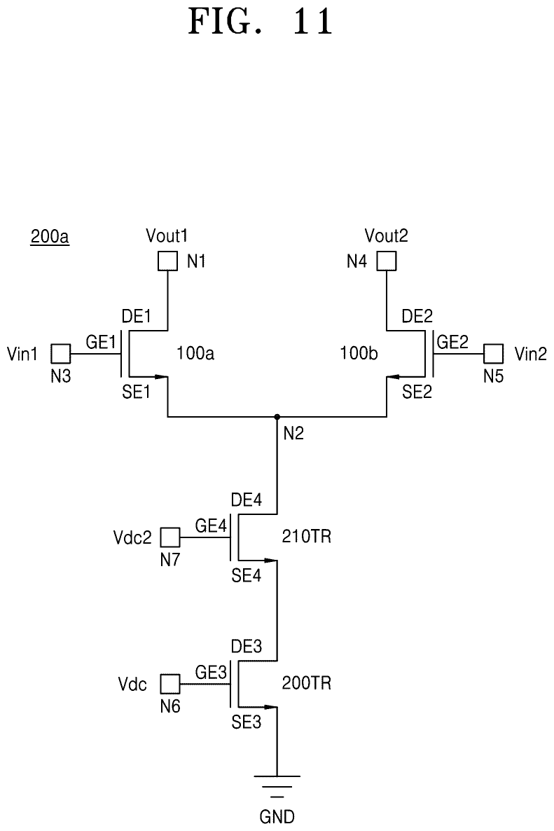

FIG. 11 is a circuit diagram illustrating a power amplifier 200a according to another embodiment.

Referring to FIG. 11, the power amplifier 200a shown in FIG. 11 is substantially the same as the power amplifier 200 shown in FIG. 9, except the power amplifier 200a further includes a fourth transistor 210TR between the common node N2 and the third transistor 200TR. The same configuration as in the previously described embodiment will be omitted or simplified, and the fourth transistor 210TR will be mainly described.

Referring to FIG. 11, the power amplifier 200a may include the first transistor 100a, the second transistor 100b, the third transistor 200TR, and the fourth transistor 200TR. The first transistor 100a and the second transistor 100b may be connected to each other in parallel, and may be connected in series to the third transistor 200TR and the fourth transistor 210TR.

The fourth transistor 210TR may include a drain DE4 connected between the common node N2 and the third transistor 200TR and connected to the common node N2, a source SE4 connected to the drain DE3 of the third transistor 200TR, and a gate GE4 connected to the second switch node N7. In addition, the gate GE4 of the fourth transistor 210TR may be connected to a separate second DC voltage source Vdc2.

As described above, the first transistor 100a and the second transistor 100b may include a group III-V semiconductor material and may be a d-mode HEMT operating normally-on. Because a threshold voltage of the first transistor 100a and a threshold voltage of the second transistor 100b have negative values, the first transistor 100a and the second transistor 100b generally have normally-on characteristics. In other words, even in an example case in which no voltage is applied to the gates GE1 and GE2 of the first transistor 100a and the second transistor 100b, current flows through a channel between two adjacent sources/drains, and when the voltage is applied to the gates GE1 and GE2, the first transistor 100a and the second transistor 100b are turned off.

The third transistor 200TR and the fourth transistor 210TR may each be a MOSFET including a group IV semiconductor material. For example, the third transistor 200TR and the fourth transistor 210TR may each be an n-type MOSFET, and threshold voltages of the third transistor 200TR and the fourth transistor 210TR may have positive values.

The power amplifier 200 of FIG. 9 uses only one silicon MOSFET (e.g., 200TR), while the power amplifier 200a of FIG. 11 has a structure in which two silicon MOSFETs (e.g., 200TR and 210TR) are cascaded. The structure of the power amplifier 200a of FIG. 11 may secure DC voltage of a source node of a GaN HEMT (e.g., 100a or 100b) at a desired level by cascading the two or more silicon MOSFETs (e.g., 200TR and 210TR) when it is difficult to secure sufficient drain-source voltages of the silicon MOSFETs (e.g., 200TR and 210TR). That is, in the power amplifier 200a of FIG. 11, both the third transistor 200TR and the fourth transistor 210TR may operate as current sources by respectively applying DC power (e.g., Vdc and Vdc2) to the gates GE3 and GE4 of the third transistor 200TR and the fourth transistor 210TR which are two silicon MOSFETs.

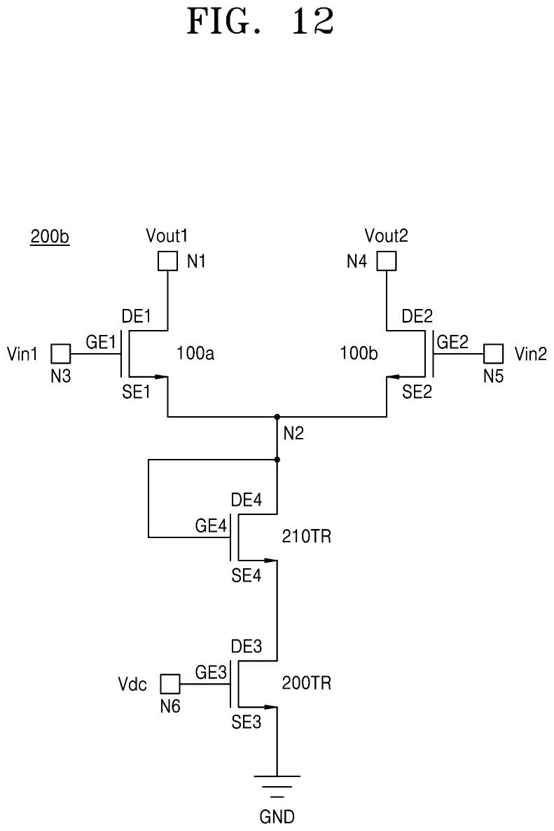

FIG. 12 is a circuit diagram illustrating a power amplifier 200b according to another embodiment.

Referring to FIG. 12, the power amplifier 200b shown in FIG. 12 is substantially the same as the power amplifier 200a shown in FIG. 11, except the gate GE4 of the fourth transistor 210TR is connected to the drain DE4. The same configuration as in the previously described embodiment will be omitted or simplified, and the fourth transistor 210TR will be mainly described.

Referring to FIG. 12, the power amplifier 200b may include the first transistor 100a, the second transistor 100b, the third transistor 200TR, and the fourth transistor 200TR. The first transistor 100a and the second transistor 100b may be connected to each other in parallel, and may be connected in series to the third transistor 200TR and the fourth transistor 210TR.

The fourth transistor 210TR may include the drain DE4 connected between the common node N2 and the third transistor 200TR and connected to the common node N2, the source SE4 connected to the drain DE3 of the third transistor 200TR, and the gate GE4 connected to the drain DE4.

As described above, the first transistor 100a and the second transistor 100b may include a group III-V semiconductor material and may be a d-mode HEMT operating normally-on. Because a threshold voltage of the first transistor 100a and a threshold voltage of the second transistor 100b have negative values, the first transistor 100a and the second transistor 100b generally have normally-on characteristics. In other words, even in an example case in which no voltage is applied to the gates GE1 and GE2 of the first transistor 100a and the second transistor 100b, current flows through a channel between two adjacent sources/drains, and when the voltage is applied to the gates GE1 and GE2, the first transistor 100a and the second transistor 100b are turned off.

The third transistor 200TR and the fourth transistor 210TR may each be a MOSFET including a group IV semiconductor material. For example, the third transistor 200TR and the fourth transistor 210TR may each be an n-type MOSFET, and threshold voltages of the third transistor 200TR and the fourth transistor 210TR may have positive values.

The power amplifier 200b shown in FIG. 12 is another embodiment of the disclosure that may be used for the same purpose as the power amplifier 200a shown in FIG. 11, and unlike the power amplifier 200a shown in FIG. 11, the gate GE4 and the drain DE4 of the fourth transistor 210TR are connected to each other so that the fourth transistor 210TR may perform an operation similar to a diode. In this case, because a voltage drop occurs between a drain-source of the fourth transistor 210TR, DC voltage of a source node of the GaN HEMT may be further increased compared to the structure of the power amplifier 200 shown in FIG. 9.

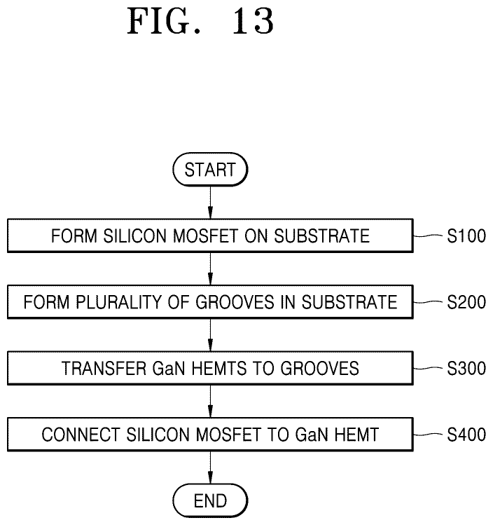

FIG. 13 is a flowchart illustrating a method of manufacturing the power amplifier 200 according to an embodiment.

Hereinafter, a method of manufacturing the power amplifier 200 will be described with reference to FIG. 13, but the configurations described with reference to FIGS. 1 to 12 may also be applied even in an example case in which there is no explicit description.

Referring to FIGS. 1 to 13, the method of manufacturing the power amplifier 200 according to an embodiment may include an operation S100 of forming a silicon MOSET (e.g., the third transistor 200TR) on a substrate (e.g., the second substrate 202), operation S200 of forming the plurality of grooves 202h in the substrate (e.g., the second substrate 202), operation S300 of transferring a GaN HEMT (e.g., the first transistor 100a or the second transistor 100b) in the grooves 202h, and operation S400 of connecting the silicon MOSET (e.g., the third transistor 200TR) to the GaN HEMT e.g., the first transistor 100a or the second transistor 100b).

According to an embodiment, in operation S100, the power amplifier 200 may include providing the second substrate 202 provided on an upper surface of the first substrate 201, and providing the third transistor 200TR on the second substrate 202. For example, the power amplifier 200 may include the first substrate 201, the second substrate 202 provided on an upper surface of the first substrate 201, and the third transistor 200TR on the second substrate 202. The first substrate 201 may be a SOI substrate including the semiconductor layer 201a and the insulating layer 201b provided on the upper surface of the semiconductor layer 201a. The second substrate 202 may include a first semiconductor material. For example, the first semiconductor material may include a group IV semiconductor material such as silicon and germanium.

The third transistor 200TR may be a MOSFET. For example, the third transistor 200TR may include the source region 203 provided on the second substrate 202, the drain region 204 provided on the second substrate 202 to be separated from the source region 203, the channel layer 205 provided between the source region 203 and the drain region 204, the gate insulating layer 208 provided on an upper surface of the channel layer 205, the gate electrode 209 provided on an upper surface of the gate insulating layer 208, the source electrode 206 provided on an upper surface of the source region 203, and the drain electrode 207 provided on an upper surface of the drain region 204. The source region 203 and the drain region 204 may be formed by doping an upper portion of the second substrate 202. Therefore, the third transistor 200TR may be a MOSFET provided on a group IV semiconductor substrate and including a group IV semiconductor material.

In operation S200, the method may including forming the groove 202h by etching the upper surface of the second substrate 202. For example, the groove 202h may be formed by partially etching the upper surface of the second substrate 202 adjacent to the third transistor 200TR. The insulating layer 210 may be provided on the third transistor 200TR, the second substrate 202, and in the groove 202h. For example, the insulating layer 210 may be formed to cover the third transistor 200TR, the upper surface of the second substrate 202, and an inner wall and a bottom surface of the groove 202h. The insulating layer 210 may include an insulating material having hydrophilicity. The insulating layer 210 may be formed by depositing at least one oxide material of, for example, SiO₂, HfOx and Al₂O₃ with a uniform thickness. The inner wall of the groove 202h may be inside of the second substrate 202 exposed by the groove 202h, and the bottom surface thereof may be the upper surface of the insulating layer 201b exposed by the groove 202h.

In operation S300, the method may include transferring the first transistor 100a and the second transistor 100b into the groove 202h. For example, the first transistor 100a and the second transistor 100b may be transferred into the groove 202h by using a wet transfer method. Before wet transfer, the substrate 101 may be previously removed from the semiconductor device 100 shown in FIG. 2 by a chemical lift-off or laser lift-off method. Then, a lower surface of the semiconductor device 100 becomes a lower surface of the buffer layer 102. The lower surface of the buffer layer 102 separated by the chemical lift-off or laser lift-off method may be very smooth and flat, and may have hydrophilic properties. On the other hand, an upper surface of the semiconductor device 100 in which the gate electrode 111 and the first to fourth sources/drains electrodes 109a, 109b, 109c, and 109d are formed is hydrophobic. Therefore, in an example case in which the buffer layer 102 of the semiconductor device 100 faces the bottom surface of the groove 202h during a wet transfer process, the semiconductor device 100 may be easily seated in the groove 202h. On the other hand, in an example case in which the gate electrode 111 and the first to fourth sources/drains electrodes 109a, 109b, 109c, and 109d face the bottom surface of the groove 202h, the semiconductor device 100 may be easily separated from the groove 202h. Therefore, the semiconductor device 100 may be transferred so that the gate electrode 111 and the first to fourth sources/drains electrodes 109a, 109b, 109c, and 109d of the semiconductor device 100 face outside of the groove 202h.

In operation S400, the method may include connecting the drain DE1 of a first d-mode HEMT (e.g., the first transistor 100a) to the first output node N1, connecting the source SE1 of the first d-mode HEMT (e.g., the first transistor 100a) to the common node N2, and connecting the gate GE1 of the first d-mode HEMT (e.g., the first transistor 100a) to the first input node N3, connecting the drain DE2 of a second d-mode HEMT (e.g., the second transistor 100b) to the second output node N4, connecting the source SE2 of the second d-mode HEMT (e.g., the second transistor 100b) to the common node N2, and the gate GE2 of the second d-mode HEMT (e.g., the second transistor 100b) to the second input node N5, and connecting the drain DE3 of an MOSFET (e.g., the third transistor 200TR) to the common node N2, connecting the source SE3 of the MOSFET (e.g., the third transistor 200TR) to the ground GND, and connecting the gate GE3 of the MOSFET (e.g., the third transistor 200TR) to the first switch node N6.

In this case, the common node N2 may function as a virtual ground at a frequency of a differential signal when the differential signal of AC (e.g., the first differential input signal Vin1 or the second differential input signal Vin2) is provided to the first input node N3 and the second input node N5. In addition, a threshold voltage of the first d-mode HEMT (e.g., the first transistor 100a) and a threshold voltage of the second d-mode HEMT (e.g., the second transistor 100b) may have negative values. The threshold voltage of the MOSFET (e.g., the third transistor 200TR) may have a positive value.

According to the power amplifier in the embodiments of the disclosure, a virtual ground is formed on source nodes of two GaN HEMTs connected to each other in parallel, and thus, miniaturization and power gain deterioration of a nitride power amplifier may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A power amplifier comprising:
a first transistor connected between a first output node and a common node, the first transistor comprising a gate connected to a first input node;
a second transistor connected between a second output node and the common node, the second transistor comprising a gate connected to a second input node; and
a third transistor connected between the common node and ground, the third transistor comprising a gate connected to a first switch node,
wherein each of the first transistor and the second transistor comprises a depletion mode (d-mode) high electron mobility transistor (HEMT) comprising a group III-V semiconductor material,
wherein each of the first transistor and the second transistor is configured to operate normally-on, and
wherein the third transistor comprises a metal oxide semiconductor field effect transistor (MOSFET) comprising a group IV semiconductor material.

2. The power amplifier of claim 1, wherein, based on a differential signal of an alternating current (AC) provided to the first input node and the second input node, the common node is configured to operate as a virtual ground at a frequency of a differential signal.

3. The power amplifier of claim 1, wherein the first switch node is connected to a first direct current (DC) voltage source.

4. The power amplifier of claim 1, wherein a threshold voltage of the first transistor is a negative value and a threshold voltage of the second transistor is a negative value.

5. The power amplifier of claim 1, wherein the third transistor is an n-type metal oxide semiconductor, and a threshold voltage of the third transistor is a positive value.

6. The power amplifier of claim 1, wherein each of the first transistor and the second transistor comprise:
a buffer layer;
a channel layer provided on an upper surface of the buffer layer, the channel layer comprising the group III-V semiconductor material;
a barrier layer provided on an upper surface of the channel layer, the barrier layer comprising a group III-V semiconductor material different from the group III-V semiconductor material of the channel layer;
a plurality of sources/drains provided to be spaced apart from each other on an upper surface of the barrier layer;
a gate insulating layer provided on the upper surface of the barrier layer and upper surfaces of the plurality of sources/drains;
a gate provided on an upper surface of the gate insulating layer so as not to overlap with the plurality of sources/drains when viewed in a direction perpendicular from the upper surface of the gate insulating layer towards the plurality of sources/drains;
a plurality of source/drain electrodes electrically connected to corresponding sources/drains among the plurality of sources/drains; and
a gate electrode electrically connected to the gate, and
wherein the plurality of source/drain electrodes have a symmetrical arrangement structure in a diagonal direction when viewed from the top.

7. The power amplifier of claim 6, wherein
the third transistor is provided on a substrate comprising the group IV semiconductor material,
the substrate comprises a plurality of grooves formed in an upper surface of the substrate, and
an insulating layer is provided on the third transistor and the plurality of grooves.

8. The power amplifier of claim 7, wherein
each of the first transistor and the second transistor is provided in a respective one of the plurality of grooves, and
the gate electrode and the plurality of source/drain electrodes of each of the first transistor and the second transistor are provided to face outside of the plurality of grooves.

9. The power amplifier of claim 7, wherein the buffer layer and the insulating layer each have hydrophilicity.

10. The power amplifier of claim 7, wherein a passivation layer is provided on the first transistor, the second transistor, and the third transistor.

11. The power amplifier of claim 1, further comprising:
a fourth transistor connected between the common node and the third transistor.

12. The power amplifier of claim 11, wherein the fourth transistor comprises a MOSFET including the group IV semiconductor material.

13. The power amplifier of claim 12, wherein a gate of the fourth transistor is connected to a second switch node.

14. The power amplifier of claim 13, wherein the second switch node is connected to a second DC voltage source.

15. The power amplifier of claim 12, wherein a gate of the fourth transistor is connected to the common node.

16. A method of manufacturing a power amplifier, the method comprising:
forming a metal oxide semiconductor field effect transistor (MOSFET) on a substrate comprising a group IV semiconductor material;
forming a plurality of grooves in an upper surface of the substrate;
transferring a first and second depletion mode (d-mode) high electron mobility transistors (HEMTs) into respective one of the plurality of grooves, each of the first and the second d-mode HEMTs comprising a group III-V semiconductor material and operate normally-on;
connecting a drain of the first d-mode HEMT to a first output node, connecting a source of the first d-mode HEMT to a common node, and connecting a gate of the first d-mode HEMT to a first input node;
connecting a drain of the second d-mode HEMT to a second output node, connecting a source of the second d-mode HEMT to the common node, and connecting a gate of the second d-mode HEMT to a second input node; and
connecting a drain of the MOSFET to the common node, a source of the MOSFET to ground, and a gate of the MOSFET to a first switch node.

17. The method of claim 16, wherein the transferring comprises providing the first and the second d-mode HEMTs on the substrate by using a wet transfer method.

18. The method of claim 16, further comprising:
forming a hydrophilic insulating layer after the forming of the plurality of grooves.

19. The method of claim 16, wherein the common node functions as a virtual ground at a frequency of a differential signal when the differential signal of an alternating current (AC) is provided to the first input node and the second input node.

20. The method of claim 16, wherein a threshold voltage of the first d-mode HEMT is a negative value and a threshold voltage of the second d-mode HEMT is a negative value.
